(19) United States
(12) Patent Application Publication
(10) Pub. No.: US 2010/0123132 A1
(43) Pub. Date: May 20, 2010

(54) THIN FILM DEVICE AND MANUFACTURING METHOD OF THE SAME

(76) Inventors: Mitsuru Nakata, Tokyo (JP); Kazushige Takechi, Tokyo (JP)

Correspondence Address: Mr. Jackson Chen, 6535 N. STATE HWY 161, IRVING, TX, 75039, US

(21) Appl. No.: 12/620,709

(22) Filed: Nov. 18, 2009

(30) Foreign Application Priority Data
Nov. 19, 2008 (JP) 2008-296068

(51) Int. Cl. H01L 29/24; H01L 21/477

(52) U.S. Cl. 257/43; 438/104; 257/E29.1; 257/E21.497

(57) ABSTRACT

To form an oxide semiconductor TFT having a fine property, which can be utilized for driving elements of a display, on a cheap glass substrate or a resin substrate such as PET that is light and flexible with fine regenerability and yield. Through radiating pulse light to an oxide semiconductor, a fine-quality oxide semiconductor film can be formed on a glass substrate or a resin substrate such as PET. This makes it possible to manufacture thin film devices having a fine property with fine regenerability and yield.

### CROSS-REFERENCE TO RELATED APPLICATION

This application is based upon and claims the benefit of priority from Japanese patent application No. 2008-296068, filed on Nov. 19, 2008, the disclosure of which is incorporated herein in its entirety by reference.

### BACKGROUND OF THE INVENTION

1. Field of the Invention

The present invention relates to a thin film device and a manufacturing method thereof. More specifically, the present invention relates to a thin film device that is structured to use an oxide semiconductor as an active layer and to a manufacturing method thereof.

2. Description of the Related Art

There have been actively conducted studies on thin film transistors (TFT) which use an oxide semiconductor film such as a film containing zinc oxide (ZnO) or a film containing indium, gallium, and zinc (indium gallium zinc oxide film (IGZO)) for a channel layer. Such oxide semiconductor can be formed at a room temperature by using sputtering or the like, so that studies regarding oxide semiconductor TFT deposited on resin substrates such as PET have also been conducted.

However, when fabricating the oxide semiconductor TFT at a low temperature such as at a room temperature, there are issues of low electron mobility, poor reliability, great hysteresis characteristic, etc. As related technical documents regarding improvements in the oxide semiconductor property, there are Japanese Patent Application Publication 2006-502597 (Patent Document 1), Japanese Unexamined Patent Publication 2008-42088 (Patent Document 2), and Japanese Unexamined Patent Publication 2007-123861 (Patent Document 3), for example.

Patent Document 1-3 refer to semiconductor film reforming methods by using annealing and laser annealing in a detailed manner, and also define methods for achieving fine electric properties of transistors.

However, high-temperature annealing is required when forming the oxide semiconductor TFT on cheap glass or a resin substrate such as PET that is light and flexible. Thus, the technique of Patent Document 1 is insufficient.

In Patent Document 1, it is depicted that the electron transfer property can be improved by improving the crystalline characteristic of the oxide semiconductor through applying annealing on the oxide semiconductor at temperatures from 300 degrees C. to 1000 degrees C. or higher for about 1 minute to 1 hour.

Such annealing processing of 1 minute or longer is effective for improving the crystalline characteristic of the oxide semiconductor. However, cheap glass substrates cannot be used for such annealing processing of 600 degrees C. or higher, and resin substrates such as PET cannot be used for the annealing of 300 degrees C. or higher. Particularly, when the oxide semiconductor TFT is formed on the resin substrate such as PET, it is desirable to execute the processing at a process temperature of 150 degrees C. or lower.

Further, Patent Document 2 depicts a technique which crystallizes an amorphous oxide semiconductor by radiating laser beams on the amorphous oxide semiconductor. However, when the amorphous oxide semiconductor is crystallized, flatness of the oxide semiconductor film becomes deteriorated and crystalline grain boundaries are generated randomly. Thus, variations in the device characteristics within the substrate surface become significant, which causes deterioration in the property and the reliability. For example, when an amorphous oxide semiconductor film (IGZO) containing indium, gallium, and zinc is crystallized, deterioration of property such as reduction in ON-current occurs. This causes deterioration in the reliability.

Furthermore, Patent Document 3 depicts a technique which forms a gate electrode, an insulating film, and an oxide semiconductor on a substrate, and applies heat on the gate electrode by a lamp for 1 minute or longer so as to crystallize the oxide semiconductor or to improve the crystalline characteristic. However, this technique increases the temperature of the oxide semiconductor via the gate electrode, so that the regenerability and yield thereof are poor.

Further, as in the case of Patent Document 2, crystallization of the oxide semiconductor generates large variations in the device property, thereby deteriorating the reliability. As a result, the devices cannot be manufactured with fine regenerability and yield.

For example, when an amorphous oxide semiconductor film (IGZO) containing indium, gallium, and zinc is crystallized, deterioration of property such as reduction in ON-current occurs, thereby causing deterioration in the reliability. Further, this technique employs long-time heating by a lamp for 1 minute or longer, so that it is not suitable for forming an oxide semiconductor TFT on cheap glass and a resin substrate such as PET that is light and flexible.

Therefore, with the related techniques described above, the oxide semiconductor TFTs having a fine property capable of being used for driving elements on a display cannot be formed on cheap glass and a resin substrate such as PET that is light and flexible with fine regenerability and yield.

### SUMMARY OF THE INVENTION

An exemplary object of the invention is to provide a thin film device, a thin film transistor, and a manufacturing method of the thin film device, which are capable of forming a fine-quality oxide semiconductor on a resin substrate such as PET and capable of manufacturing electronic components such as ICs having a fine property with fine regenerability and yield.

In order to achieve the foregoing exemplary object, the thin film device according to an exemplary aspect of the invention is a thin film device which uses an oxide semiconductor film deposited on a substrate as an active layer, wherein the oxide semiconductor film is an amorphous oxide semiconductor to which pulse light is radiated. This makes it possible to achieve a fine electric property.

Further, in order to achieve the foregoing exemplary object, the thin film device manufacturing method according to another exemplary aspect of the invention is a thin film device manufacturing method, which includes: forming an oxide semiconductor film made with an amorphous oxide semiconductor on a substrate; and radiating pulse light to the oxide semiconductor film to use the oxide semiconductor film made with the amorphous oxide semiconductor as an active layer. This makes it possible to manufacture the thin film device of a fine electric property.

### BRIEF DESCRIPTION OF THE DRAWINGS

FIG. 1A is an illustration showing thin film transistor manufacturing steps of a first exemplary embodiment according to the invention, in which it is explanatory illustration showing the steps until forming an oxide semiconductor film (semiconductor active layer);

FIG. 1B is an illustration showing thin film transistor manufacturing steps of a first exemplary embodiment according to the invention, in which it is explanatory illustration showing the steps until forming an oxide semiconductor film (semiconductor active layer);

FIG. 1C is an illustration showing thin film transistor manufacturing steps of a first exemplary embodiment according to the invention, in which it is explanatory illustration showing the steps until forming an oxide semiconductor film (semiconductor active layer);

FIG. 1D is an illustration showing the thin film transistor manufacturing steps of a first exemplary embodiment according to the invention, in which it is explanatory illustration for showing steps of forming source/drain electrodes;

FIG. 1E is an illustration showing the thin film transistor manufacturing steps of a first exemplary embodiment according to the invention, in which it is explanatory illustration for showing steps of forming source/drain electrodes;

FIG. 2 is an explanatory chart showing the property of the thin film transistor manufactured by the first exemplary embodiment of the invention;

FIG. 3A is an explanatory illustration showing a part of the manufacturing steps of a thin film transistor according to a second exemplary embodiment of the invention;

FIG. 3B is a chart for describing the property of the thin film transistor obtained by the steps of FIG. 3A;

FIG. 4A is an illustration showing thin film transistor manufacturing steps of a third exemplary embodiment according to the invention, in which it is explanatory illustration showing the steps until forming an oxide semiconductor film (semiconductor active layer);

FIG. 4B is an illustration showing thin film transistor manufacturing steps of a third exemplary embodiment according to the invention, in which it is explanatory illustration showing steps until forming an oxide semiconductor film (semiconductor active layer);

FIG. 4C is an illustration showing thin film transistor manufacturing steps of a third exemplary embodiment according to the invention, in which it is explanatory illustration showing the steps until forming an oxide semiconductor film (semiconductor active layer);

FIG. 4D is an illustration showing the thin film transistor manufacturing steps following the step of FIG. 4C, in which it is explanatory illustration for showing steps of forming source/drain electrodes;

FIG. 4E is an illustration showing the thin film transistor manufacturing steps following the step of FIG. 4D, in which it is explanatory illustration for showing steps of forming source/drain electrodes;

FIG. 5A is an illustration showing thin film transistor manufacturing steps of a fourth exemplary embodiment according to the invention, in which it is explanatory illustration showing the steps until forming an oxide semiconductor film (semiconductor active layer);

FIG. 5B is an illustration showing thin film transistor manufacturing steps of a fourth exemplary embodiment according to the invention, in which it is explanatory illustration showing the steps until forming an oxide semiconductor film (semiconductor active layer);

FIG. 5C is an illustration showing thin film transistor manufacturing steps of a fourth exemplary embodiment according to the invention, in which it is explanatory illustration showing the steps until forming an oxide semiconductor film (semiconductor active layer);

FIG. 5D is an illustration showing the thin film transistor manufacturing steps following the step of FIG. 5C, in which it is explanatory illustration for showing steps of forming a gate electrode;

FIG. 5E is an illustration showing the thin film transistor manufacturing steps following the step of FIG. 5D, in which it is explanatory illustration for showing steps of forming a gate electrode;

FIG. 5F is an illustration showing the thin film transistor manufacturing steps following the step of FIG. 5E, in which it is explanatory illustration for showing steps of forming a gate electrode;

FIG. 6A is an illustration showing thin film transistor manufacturing steps of a fifth exemplary embodiment according to the invention, in which it is explanatory illustration showing the steps until forming an oxide semiconductor film (semiconductor active layer);

FIG. 6B is an illustration showing thin film transistor manufacturing steps of a fifth exemplary embodiment according to the invention, in which it is explanatory illustration showing the steps until forming an oxide semiconductor film (semiconductor active layer);

FIG. 6C is an illustration showing thin film transistor manufacturing steps of a fifth exemplary embodiment according to the invention, in which it is explanatory illustration showing the steps until forming an oxide semiconductor film (semiconductor active layer);

FIG. 6D is an illustration showing the thin film transistor manufacturing steps following the step of FIG. 6C, in which it is explanatory illustration for showing steps of forming a gate electrode and an interlayer insulating film;

FIG. 6E is an illustration showing the thin film transistor manufacturing steps following the step of FIG. 6D, in which it is explanatory illustration for showing steps of forming a gate electrode and an interlayer insulating film;

FIG. 6F is an illustration showing the thin film transistor manufacturing steps following the step of FIG. 6E, in which it is explanatory illustration for showing steps of forming a gate electrode and an interlayer insulating film;

FIG. 6G is an illustration showing the thin film transistor manufacturing steps following the step of FIG. 6F, in which it is explanatory illustration for showing steps of forming source/drain electrodes;

FIG. 6H is an illustration showing the thin film transistor manufacturing steps following the step of FIG. 6G, in which it is explanatory illustration for showing steps of forming source/drain electrodes;

FIG. 7A is an illustration showing thin film transistor manufacturing steps of a sixth exemplary embodiment according to the invention, in which it is explanatory illustration showing the steps until forming a protective insulating film on an oxide semiconductor film (semiconductor active layer);

FIG. 7B is an illustration showing thin film transistor manufacturing steps of a sixth exemplary embodiment according to the invention, in which it is explanatory illustration showing the steps until forming a protective insulating film on an oxide semiconductor film (semiconductor active layer);

FIG. 7C is an illustration showing thin film transistor manufacturing steps of a sixth exemplary embodiment according to the invention, in which it is explanatory illustration showing the steps until forming a protective insulating film on an oxide semiconductor film (semiconductor active layer);

FIG. 8A is an illustration showing a part of thin film transistor manufacturing steps according to a seventh exemplary embodiment of the invention, in which it is explanatory illustration for showing steps of forming source/drain electrodes and a protective insulating film;

FIG. 8B is an illustration showing a part of thin film transistor manufacturing steps according to a seventh exemplary embodiment of the invention, in which it is explanatory illustration for showing steps of forming source/drain electrodes and a protective insulating film;

FIG. 9 is an explanatory chart showing the property of the thin film transistor obtained by the method shown in FIG. 8A and FIG. 8B;

FIG. 10A is an illustration showing a part of thin film transistor manufacturing steps according to an eighth exemplary embodiment of the invention, in which it is explanatory illustration for showing steps of forming a gate electrode and a protective insulating film;

FIG. 10B is an illustration showing a part of thin film transistor manufacturing steps according to an eighth exemplary embodiment of the invention, in which it is explanatory illustration for showing steps of forming a gate electrode and a protective insulating film;

FIG. 11A is an illustration showing a part of thin film transistor manufacturing steps according to a ninth exemplary embodiment of the invention, in which it is explanatory illustration for showing steps of forming a gate electrode and a protective insulating film;

FIG. 11B is an illustration showing a part of thin film transistor manufacturing steps according to a ninth exemplary embodiment of the invention, in which it is explanatory illustration for showing steps of forming a gate electrode and a protective insulating film;

FIG. 12A is an illustration showing a part of thin film transistor manufacturing steps according to a tenth exemplary embodiment of the invention, in which it is explanatory illustration for showing steps until forming an oxide semiconductor film (semiconductor active layer) and a channel protective film;

FIG. 12B is an illustration showing a part of thin film transistor manufacturing steps according to a tenth exemplary embodiment of the invention, in which it is explanatory illustration for showing steps until forming an oxide semiconductor film (semiconductor active layer) and a channel protective film;

FIG. 12C is an illustration showing a part of thin film transistor manufacturing steps according to a tenth exemplary embodiment of the invention, in which it is explanatory illustration for showing steps until forming an oxide semiconductor film (semiconductor active layer) and a channel protective film;

FIG. 12D is an illustration showing a part of thin film transistor manufacturing steps according to a tenth exemplary embodiment of the invention, in which it is explanatory illustration for showing steps until forming an oxide semiconductor film (semiconductor active layer) and a channel protective film;

FIG. 12E is an illustration showing a part of thin film transistor manufacturing steps according to a tenth exemplary embodiment of the invention, in which it is explanatory illustration for showing steps until forming an oxide semiconductor film (semiconductor active layer) and a channel protective film;

FIG. 13A is an illustration showing a part of thin film transistor manufacturing steps according to an eleventh exemplary embodiment of the invention, in which it is explanatory illustration for showing steps until forming a second silicon oxide film and a gate electrode;

FIG. 13B is an illustration showing a part of thin film transistor manufacturing steps according to an eleventh exemplary embodiment of the invention, in which it is explanatory illustration for showing steps until forming a second silicon oxide film and a gate electrode;

FIG. 13C is an illustration showing a part of thin film transistor manufacturing steps according to an eleventh exemplary embodiment of the invention, in which it is explanatory illustration for showing steps until forming a second silicon oxide film and a gate electrode;

FIG. 13D is an illustration showing a part of thin film transistor manufacturing steps according to an eleventh exemplary embodiment of the invention, in which it is explanatory illustration for showing steps until forming a second silicon oxide film and a gate electrode;

FIG. 13E is an illustration showing a part of thin film transistor manufacturing steps according to an eleventh exemplary embodiment of the invention, in which it is explanatory illustration for showing steps until forming a second silicon oxide film and a gate electrode;

FIG. 14A is an illustration showing a part of thin film transistor manufacturing steps according to a twelfth exemplary embodiment of the invention, in which it is explanatory illustration for showing steps until forming an oxide semiconductor film (semiconductor active layer), an ITO film, and a metal film;

FIG. 14B is an illustration showing a part of thin film transistor manufacturing steps according to a twelfth exemplary embodiment of the invention, in which it is explanatory illustration for showing steps until forming an oxide semiconductor film (semiconductor active layer), an ITO film, and a metal film;

FIG. 14C is an illustration showing a part of thin film transistor manufacturing steps according to a twelfth exemplary embodiment of the invention, in which it is explanatory illustration for showing steps until forming an oxide semiconductor film (semiconductor active layer), an ITO film, and a metal film;

FIG. 14D is an illustration showing a part of thin film transistor manufacturing steps according to a twelfth exemplary embodiment of the invention, in which it is explanatory illustration for showing steps until forming an oxide semiconductor film (semiconductor active layer), an ITO film, and a metal film; and

FIG. 14E is an illustration showing a part of thin film transistor manufacturing steps according to a twelfth exemplary embodiment of the invention, in which it is explanatory illustration for showing steps until forming an oxide semiconductor film (semiconductor active layer), an ITO film, and a metal film.

### DETAILED DESCRIPTION OF THE EXEMPLARY EMBODIMENTS

### First Exemplary Embodiment

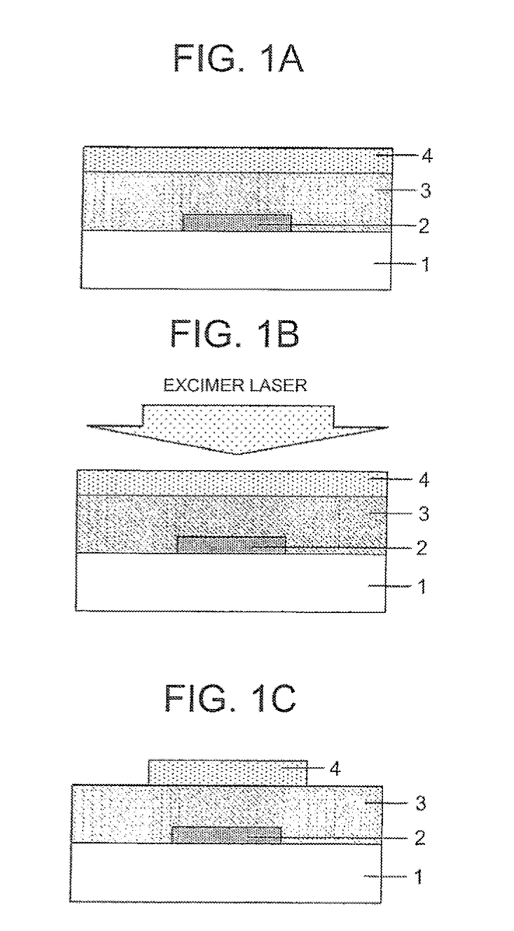

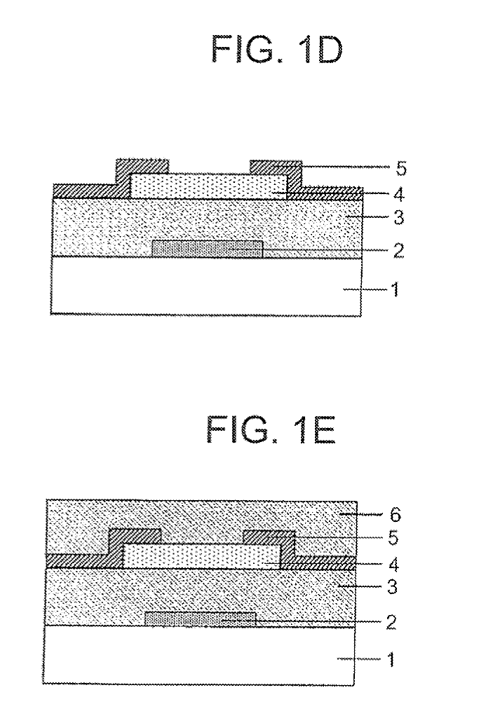

Hereinafter, a first exemplary embodiment of the invention will be described by referring to FIG. 1-FIG. 5.

FIG. 1A-FIG. 1E are illustrations of steps showing a series of methods for manufacturing a thin film device (TFT) according to the first exemplary embodiment.

When manufacturing the thin film device (TFT), first, as shown in FIG. 1A, chromium of 50 nm is deposited on an insulating substrate 1, and then patterning is conducted to form a gate electrode 2 with the chromium. Thereafter, a silicon oxide film of 100 nm is deposited as a gate insulating film 3 that covers the gate electrode 2. Then, an oxide semiconductor film 4 of 20 nm is deposited on the gate insulating film 3 as an active layer.

Note here that, in the first exemplary embodiment, the oxide semiconductor film (IGZO: indium gallium zinc oxide film) 4 containing indium, gallium, and zinc is deposited by sputtering as the oxide semiconductor film.

This oxide semiconductor film (IGZO film) 4 is amorphous. The sputter target used herein is an IGZO sinter. The composition ratio of the IGZO target is 1:1:1:4 (indium:gallium:zinc:oxygen).

In the first exemplary embodiment, the oxide semiconductor film formed by using the sputter target having the composition ratio of 1:1:1:4 (indium:gallium:zinc:oxygen) is described as the oxide semiconductor film 4. However, the composition ratio is not limited only to that. In addition, while the oxide semiconductor film containing indium, gallium, and zinc is described above as the oxide semiconductor film 4, it is not limited only to such type. An oxide semiconductor such as a ZnO film, which contains at least one element selected from indium, gallium, zinc, and tin, may be used as well.

Further, instead of the amorphous oxide semiconductor film 4, it is possible with the first exemplary embodiment to use a polycrystalline oxide semiconductor film such as a ZnO film or a crystalline oxide semiconductor.

When the oxide semiconductor containing indium, gallium, zinc, and tin is used as the oxide semiconductor film 4, it is possible to form the film at a room temperature. Thus, a resin substrate such as PET, a resin film, a glass substrate, or the like can be used as a substrate. Furthermore, a substrate such as a silicon substrate or a metal substrate can be used as well. After forming the gate insulating film 3, it is preferable to deposit the oxide semiconductor film 4 continuously without exposing the gate insulating film 3 to the air.

Then, pulse light is radiated to the IGZO film that is the oxide semiconductor film 4. In the first exemplary embodiment, laser light of 308 nm wavelength generated by an XeCl excimer laser is radiated to the IGZO film 4 as the pulse light, which can be absorbed by the IGZO film, towards the IGZO film 4 as in FIG. 18.

The irradiation area of the pulse light (the laser light) is 400 μm (minor axis)×150 mm (major axis), and the pulse light is scan-radiated at an interval of 200 μm along the minor axis direction. That is, for an arbitrary irradiating region, the pulse light is radiated twice. Regarding the irradiation time of the pulse light used in the first exemplary embodiment, the pulse width (time during which intensity of at least one half of the maximum value of the irradiation intensity per time is maintained) is set as 20 nsec.

The pulse width is merely presented as a way of example, and it is not limited to be 20 nsec. For the pulse width, it is preferable to be the pulse width with which the temperature of the oxide semiconductor film 4 becomes equal to or higher than the peripheral temperature and the pulse width with which the oxide semiconductor film 4 is not crystallized, melted, or sublimated.

Furthermore, the pulse width may be smaller than a value with which damage to the substrates, such as exfoliation of the oxide semiconductor film 4 from the substrate 1, contraction of the substrate 1, and bending of the substrate, do not occur. Specifically, the pulse width is preferable to be between 1-1000 ns.

However, the preferable pulse width value largely changes depending on the structure of the elements of the oxide semiconductor film 4, film depositing method, film quality, film thickness, absorption rate for the radiated light, and the like. Therefore, the pulse width may be set as appropriate in accordance with the oxide semiconductor film 4 to be used. Further, the preferable pulse width changes largely also depending on the thermal conductivity of the substrate 1, the absorption rate for the radiated light, and the like, so that it may be set as appropriate in accordance with the substrate to be used.

The irradiation intensity is set as 150 mJ/cm². This value of the irradiation intensity is presented merely as a way of example, and it is not limited to 150 mJ/cm². The irradiation intensity may be set as any value as long as it is between the value with which the oxide semiconductor film 4 becomes equal to or higher than the peripheral temperature and the value with which the oxide semiconductor film 4 is not crystallized, melted, or sublimated.

Further, it is preferable to set the irradiation intensity to be less than the value with which damage to the substrates, such as exfoliation of the oxide semiconductor film 4 from the substrate 1, contraction of the substrate 1, and bending of the substrate, do not occur. Specifically, it is preferable to be 1-1000 mJ/cm².

However, the preferable irradiation intensity value largely changes depending on the structure of the elements of the oxide semiconductor film 4, film depositing method, film quality, film thickness, absorption rate for the radiated light, and the like. Therefore, the pulse intensity may be set as appropriate in accordance with the oxide semiconductor film 4 to be used. Further, the preferable pulse intensity value changes largely also depending on the thermal conductivity of the substrate 1, the absorption rate for the irradiated light, and the like, so that it may be set as appropriate in accordance with the substrate to be used.

For the radiated pulse light, it is preferable to contain the wavelength that can be absorbed by the oxide semiconductor film 4. Specifically, it is preferable to contain the wavelength of 400 nm or less or the wavelength of 800 nm or higher. The preferable wavelength of the pulse light largely changes depending on the structure of the elements of the oxide semiconductor film 4, film depositing method, film quality, film thickness, absorption rate for the radiated light, and the like. Therefore, the wavelength of the pulse light may be set as appropriate in accordance with the oxide semiconductor film 4 to be used. Further, the preferable wavelength of the pulse light changes largely also depending on the thermal conductivity of the substrate 1, the absorption rate for the radiated light, and the like, so that it may be set as appropriate in accordance with the substrate to be used.

The preferable irradiation area and the preferable number of irradiations largely change depending on the structure of the elements of the oxide semiconductor film 4, film depositing method, film quality, film thickness, absorption rate for the radiated light, and the like. Therefore, those values may be set as appropriate in accordance with the oxide semiconductor film 4 to be used. Further, the preferable irradiation area and the preferable number of irradiations largely change also depending on the thermal conductivity of the substrate, the absorption rate for the radiated light, and the like, so that it may be set as appropriate in accordance with the substrate 1 to be used.

Furthermore, the pulse light is not limited to the laser light generated by the XeCl excimer laser but may be laser light generated by other excimer lasers such as a KrF laser, an ArF laser, an XeF laser, or may be laser light generated by a solid-state laser such as a YAG laser. Alternatively, as the pulse light, it is also possible to use light of an Xe flash lamp that includes the light with a wavelength range of 200 nm-1500 nm.

Through radiating the pulse light, reforming of the film by the temperature increase of the oxide semiconductor film 4 and reforming of the film by absorption of the light can be executed simultaneously. Larger effects can be expected with the film reforming by radiation of the pulse light than the case of the film reforming achieved only by the increase in the temperature of the oxide semiconductor film 4 by using an oven or the like.

Further, through controlling the pulse width and the irradiation intensity of the pulse light, it is possible to suppress transmission of the increased heat of the oxide semiconductor film 4 to the substrate. Therefore, the glass substrate and the resin substrate can be used with this process.

Furthermore, as the irradiation condition of the pulse light, the pulse width and the irradiation intensity may be set to the values with which the temperature of the oxide semiconductor does not increase. Even if the temperature of the oxide semiconductor film 4 does not increase by radiation of the pulse light, effects of improvements can be expected when the oxide semiconductor simply absorbs the light with the wavelength of 400 nm or less or the light with the wavelength of 800 nm or higher.

Next, the IGZO film is patterned to a prescribed shape as the oxide semiconductor film 4 as in FIG. 1C. Subsequently, as shown in FIG. 1D, a source/drain metal film is deposited over the gate insulating film 3 and the oxide semiconductor film 4, and the source/drain metal film is patterned to form source/drain electrodes 5.

Thereafter, as shown in FIG. 1E, a silicon oxide film as a protective insulating film 6 is deposited to cover the source/drain electrodes 5 as well as the oxide semiconductor film (IGZO film) 4 that is exposed from the source/drain electrodes 5. In order to implement input and output of electric signals, a part of the gate insulating film 3 and the protective insulating film 6 is etched to form an electrode by opening a part of the gate electrode 2 and the source/drain electrodes 5. Thereby, the thin film transistor (TFT) can be fabricated.

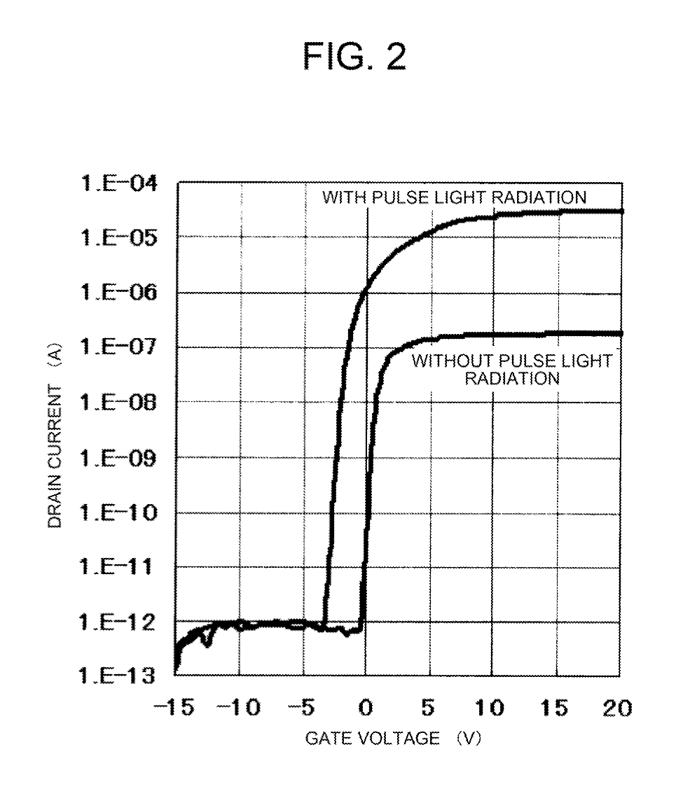

FIG. 2 shows the electric properties (drain current-gate voltage properties) of the TFT fabricated without radiating the XeCl excimer laser (without pulse light radiation) and the TFT fabricated in the above-described manner by radiating the XeCl excimer laser (with pulse light radiation). Channel length and channel width are both 100 μm, and the drain voltage is 10 V.

The drain current at the gate voltage of 20 V is 1.9×10⁻⁷ A in the TFT property without pulse light radiation. In the meantime, the drain current at the gate voltage of 20 V is 3.3×10⁻⁵ A in the TFT property with pulse light radiation, which is an improved value of two digits or more. Further, the electric property of the TFT with pulse light radiation exhibits a smaller hysteresis characteristic than the electric property of the TFT without pulse light radiation, and has a better performance in the switching property. That is, it is evident that the TFT property is improved when the pulse light is radiated to the oxide semiconductor film.

In the first exemplary embodiment, the pulse light is radiated after forming the oxide semiconductor film 4. However, the present invention is not limited only to such case. The pulse light may be radiated in any steps after forming the oxide semiconductor film 4. For example, the pulse light may be radiated after patterning the oxide semiconductor film 4 and forming the source/drain electrodes 5. Further, the pulse light may be radiated as many times as necessary.

Furthermore, while the first exemplary embodiment has been described by referring to the case of the thin film transistor, the present invention is not limited to such case. The step of radiating the pulse light may be employed when manufacturing thin film diodes and thin film devices such as solar batteries using the oxide semiconductor film 4. Also, in the first exemplary embodiment, the IGZO film (oxide semiconductor film) 4 after radiating the pulse light is amorphous. This can be verified by conducting an analysis such as X-ray diffraction.

Further, in the thin film device manufacturing steps of the first exemplary embodiment, the temperature of the substrate does not reach up to 150 degrees C. or higher. Because of this, it is possible to use a glass substrate or a resin substrate for the substrate 1.

Accordingly, the first exemplary embodiment makes it possible to form the fine-quality oxide semiconductor film 4 on a glass substrate or a resin substrate such as PET. Therefore, thin film transistors or other thin film devices having an excellent property can be manufactured with fine regenerability and yield.

As an exemplary advantage according to the invention, the present invention makes it possible to form the fine-quality oxide semiconductor on a glass substrate or a resin substrate such as PET as an active layer, thereby making it possible to manufacture the electronic components such as ICs having a tine property with fine regenerability and yield.

### Second Exemplary Embodiment

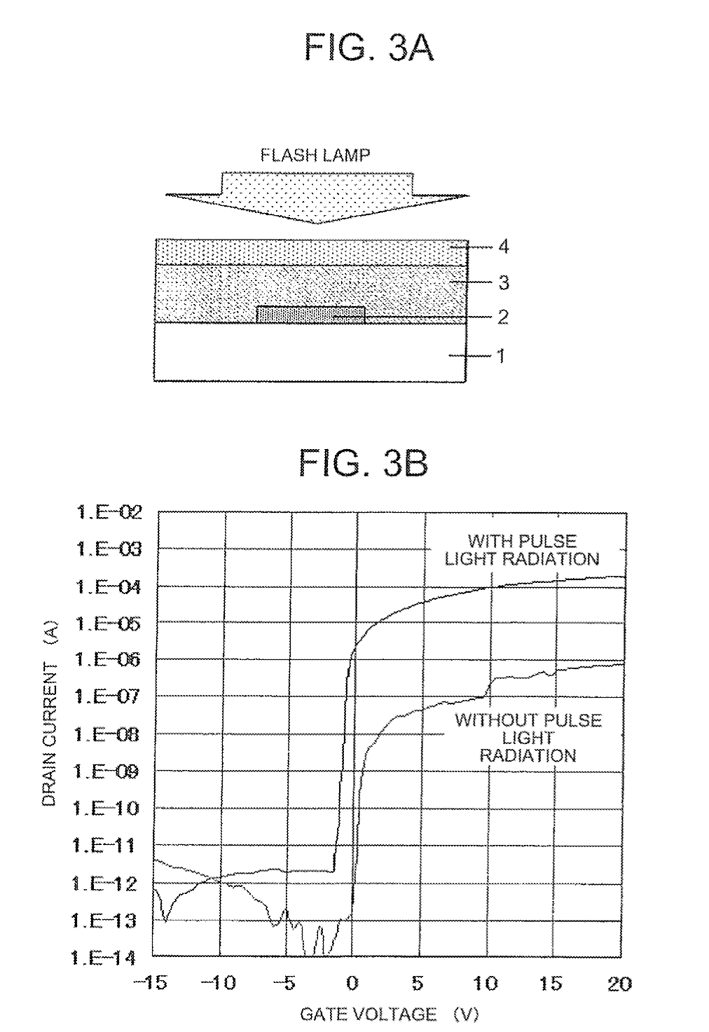

Next, a TFT (thin film transistor) manufacturing method according to a second exemplary embodiment will be described by referring to FIG. 3 while utilizing FIG. 1A-FIG 1E of the first exemplary embodiment.

Note here that same reference numerals are used for the same structural members as those of the first exemplary embodiment described above (this also applies to a third exemplary embodiment and thereafter).

First, referring to FIG. 3A, chromium of 50 nm is deposited on an insulating substrate 1, and it is patterned to form a gate electrode 2 with the chromium, as in the case of FIG. 1A-FIG. 1E described above. Thereafter, a silicon oxide film of 100 nm is deposited as a gate insulating film 3 that covers the gate electrode 2. Then, an oxide semiconductor film 4 is deposited on the gate insulating film 3 as an active layer.

In the second exemplary embodiment, an oxide semiconductor (IGZO) of 20 nm containing indium, gallium, and zinc is deposited by sputtering as the oxide semiconductor film 4. This IGZO film 4 is amorphous. The sputter target used herein is an IGZO sinter. The composition ratio of the IGZO target is 1:1:1:4 (indium:gallium:zinc:oxygen).

In the second exemplary embodiment, the oxide semiconductor film formed by using the sputter target having the composition ratio of 1:1:1:4 (indium:gallium:zinc:oxygen) is described as the oxide semiconductor film 4. However, the composition ratio is not limited only to that. In addition, while the oxide semiconductor film containing indium, gallium, and zinc is described above as the oxide semiconductor film 4, it is not limited only to such type. An oxide semiconductor film such as a ZnO film, which contains at least one element selected from indium, gallium, zinc, and tin, may be used as well.

Further, while the second exemplary embodiment has been described by using an amorphous oxide semiconductor film as the oxide semiconductor film 4, the present invention is not limited only to such case. As the material thereof, it is possible to use a polycrystalline oxide semiconductor film such as a ZnO film or a crystalline oxide semiconductor.

When the oxide semiconductor containing indium, gallium, zinc, and tin is used as the oxide semiconductor film 4, it is possible to form the film at a room temperature. Thus, a resin substrate such as PET, a resin film, a glass substrate, or the like can be used as the substrate 1. Furthermore, a substrate such as a silicon substrate or a metal substrate can be used as well. After forming the gate insulating film 3, it is preferable to deposit the oxide semiconductor film 4 continuously without exposing the gate insulating film 3 to the air.

Then, pulse light is radiated to the IGZO film that is the oxide semiconductor film 4. The second exemplary embodiment uses an Xe (xenon) flash lamp for this. The radiation light generated by the flash lamp used in this case contains light with wavelength of 200-1500 nm, which can be absorbed by the IGZO film. As in FIG. 3A, the light of the flash lamp is radiated towards the oxide semiconductor film (IGZO) film 4.

The irradiation area of the pulse light (light of the lamp) is 150 mm×150 mm, and the light is radiated once to the irradiation region. Regarding the irradiation time of the pulse light used in the second exemplary embodiment, the pulse width is set as 1 msec.

The pulse width is merely presented as a way of example, and it is not limited to be 1 msec. For the pulse width, it is preferable to be between the pulse width with which the oxide semiconductor film 4 becomes equal to or higher than the peripheral temperature and the pulse width with which the oxide semiconductor film 4 is not crystallized, melted, or sublimated.

Furthermore, the pulse width may be smaller than a value with which damages to the substrates, such as exfoliation of the oxide semiconductor film 4 from the substrate 1, contraction of the substrate 1, and bending of the substrate, do not occur. Specifically, the pulse width is preferable to be between 0.001-100 msec.

However, as in the case of the first exemplary embodiment, the preferable pulse width value largely changes depending on the material, film thickness, and the like of the oxide semiconductor film 4 or the material and the like of the substrate 1. Therefore, the pulse width may be set as appropriate in accordance with the oxide semiconductor film 4 and the substrate 1 to be used.

The irradiation intensity is set as 5 J/cm². This value of the irradiation intensity is presented merely as a way of example, and it is not limited to 5 J/cm². The irradiation intensity may be set as any value as long as it is between the value with which the temperature of the oxide semiconductor film 4 becomes equal to or higher than the peripheral temperature and the value with which the oxide semiconductor film 4 is not crystallized, melted, or sublimated. Further, it is preferable to set the irradiation intensity to be less than the value with which damages to the substrates, such as exfoliation of the oxide semiconductor film 4 from the substrate 1, contraction of the substrate 1, and bending of the substrate, do not occur. Specifically, it is preferable to be 0.01-100 J/cm².

However, as in the case of the first exemplary embodiment, the preferable irradiation intensity value largely changes depending on the material of the oxide semiconductor film 4, absorption rate for the radiated light and the like, or the material and the like of the substrate 1, and the like. Therefore, the pulse intensity may be set as appropriate in accordance with the oxide semiconductor film 4 and the substrate 1 to be used.

For the radiated pulse light, it is preferable to contain the wavelength that can be absorbed by the oxide semiconductor. Specifically, it is preferable to contain light with the wavelength of 400 nm or less or the light with the wavelength of 800 nm or higher. As in the case of the first exemplary embodiment, the preferable wavelength of the pulse slight may be set as appropriate in accordance with the oxide semiconductor film 4 or the substrate to be used.

Further, the preferable irradiation area and the number of irradiations may also be set as appropriate in accordance with the oxide semiconductor film 4 or the substrate to be used as in the case of the first exemplary embodiment described above.

Through radiating the pulse light as described above, film reforming by the temperature increase of the oxide semiconductor film 4 and film reforming by absorption of the light can be executed simultaneously. Larger effects can be expected with the film reforming by radiation of the pulse light than the case of the film reforming achieved only by the increase in the temperature of the oxide semiconductor using an oven or the like.

Further, through controlling the pulse width and the irradiation intensity of the pulse light, it is possible to suppress transmission of the increased heat of the oxide semiconductor film 4 to the substrate 1. Therefore, the glass substrate and the resin substrate can be used with this process. Furthermore, as the irradiation condition of the pulse light, the pulse width and the irradiation intensity may be set to the values with which the temperature of the oxide semiconductor film 4 does not increase. Even if the temperature of the oxide semiconductor film 4 does not increase by radiation of the pulse light, effects of improvements can be expected when the oxide semiconductor simply absorbs the light.

Next, the oxide semiconductor film (IGZO film) 4 is patterned to a prescribed shape as in the case shown in FIG. 1C. Subsequently, as in the case shown in FIG. 1D, a source/drain metal film is deposited over the gate insulating film 3 and the oxide semiconductor film 4, and the source/drain metal film is patterned to form source/drain electrodes 5.

Thereafter, as in the case shown in FIG. 1E, a silicon oxide film as a protective insulating film 6 is deposited to cover the source/drain electrodes 5 as well as the oxide semiconductor film (IGZO film) 4 that is exposed from the source/drain electrodes 5. In order to implement input and output of electric signals, a part of the gate insulating film 3 and the protective insulating film 6 is etched to form an electrode by opening a part of the gate electrode 2 and the source/drain electrodes 5. Thereby, the thin film transistor (TFT) can be fabricated.

FIG. 3B shows the electric properties (drain current-gate voltage properties) of the TFT fabricated without radiating the Xe flash lamp (without pulse light radiation) and the TFT fabricated in the above-described manner by radiating the Xe flash lamp (with pulse light radiation).

Channel length is 400 μm, channel width is 200 μm, and the drain voltage is 10 V. The drain current at the gate voltage of 20 V is 7.9×10⁻⁷ A in the TFT property without pulse light radiation. In the meantime, the drain current at the gate voltage of 20 V is 1.9×10⁴ A in the TFT property with pulse light radiation, which is an improved value of two digits or more.

Further, the electric property of the TFT with pulse light radiation exhibits a smaller hysteresis characteristic than the electric property of the TFT without pulse light radiation, and has a better performance in the switching property. That is, it is evident that the TFT property is improved when the pulse light is radiated to the oxide semiconductor film.

In the second exemplary embodiment, the pulse light is radiated after forming the oxide semiconductor film 4. However, the present invention is not limited only to such case. The pulse light may be radiated in any steps after forming the oxide semiconductor film 4. For example, the pulse light may be radiated after patterning the oxide semiconductor and forming the source/drain electrodes. Further, the pulse light may be radiated as many times as necessary.

Furthermore, while the second exemplary embodiment has been described by referring to the case of the thin film transistor, the present invention is not limited to such case. The step of radiating the pulse light may be employed when manufacturing thin film diodes and thin film devices such as solar batteries using the oxide semiconductor.

Also, in the second exemplary embodiment, the IGZO film (oxide semiconductor film) 4 after radiating the pulse light is amorphous. This can be verified by conducting an analysis such as X-ray diffraction.

Further, in the thin film device manufacturing steps of the second exemplary embodiment, the temperature of the substrate 1 does not reach up to 150 degrees C. or higher. Because of this, it is possible to use a glass substrate or a resin substrate for the substrate 1. With the second exemplary embodiment described above, it is also possible to achieve the same effects as those of the first exemplary embodiment described above.

Other structures and effects thereof are the same as those of the first exemplary embodiment described above.

### Third Exemplary Embodiment

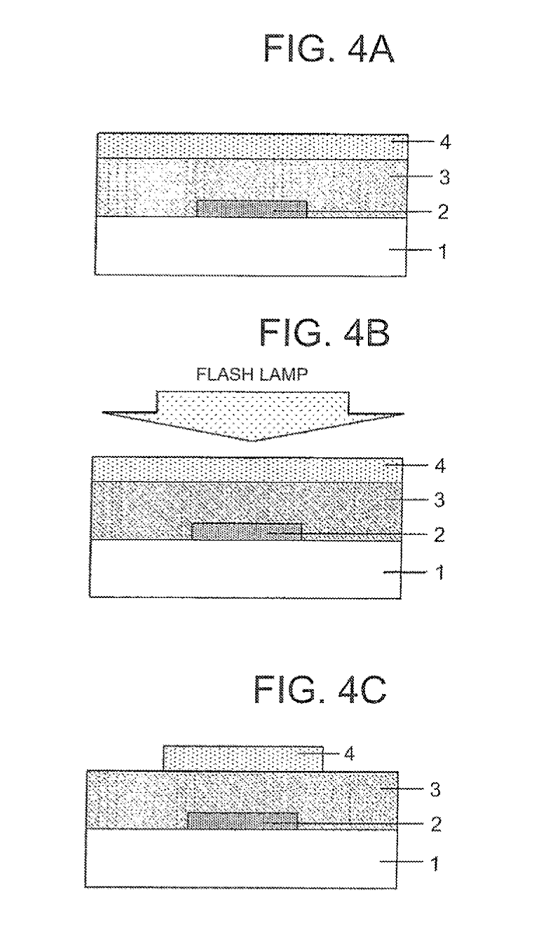

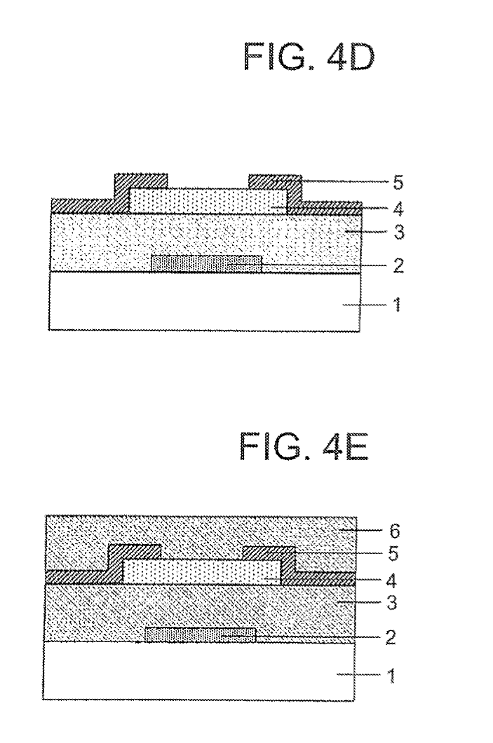

Next, a third exemplary embodiment will be described by referring to FIG. 4A-FIG. 4E.

FIG. 4A-FIG. 4E are illustrations of a series of manufacturing steps which can manufacture another TFT (thin film transistor) that is equivalent to the TFT obtained in the first exemplary embodiment described above.

Hereinafter, this will be described.

First, as shown in FIG. 4A, chromium of 50 nm is deposited on an insulating substrate 1, and then patterning is conducted to form a gate electrode 2 with the chromium. Thereafter, a silicon oxide film of 100 nm is deposited as a gate insulating film 3 that covers the gate electrode 2.

Then, an oxide semiconductor film 4 is deposited on the gate insulating film 3 as an active layer. In the third exemplary embodiment, zinc oxide (ZnO) of 10 nm is deposited by sputtering as the oxide semiconductor film 4. The ZnO film (oxide semiconductor film) 4 is polycrystalline. The used sputter target is a ZnO sinter. While the case of using ZnO as the oxide semiconductor film 4 is described herein, the present invention is not limited only to such case. It is also possible to use an oxide semiconductor film which contains at least one element selected from indium, gallium, zinc, and tin.

Further, while the third exemplary embodiment has been described by using a polycrystalline oxide semiconductor film as the oxide semiconductor film 4, the present invention is not limited only to such case. It is possible to use an amorphous oxide semiconductor film or a crystalline oxide semiconductor. When the oxide semiconductor containing indium, gallium, zinc, and tin is used as the oxide semiconductor film 4, it is possible to form the film at a room temperature. Thus, a resin substrate such as PET, a resin film, a glass substrate, or the like can be used as the substrate 1. Furthermore, a substrate such as a silicon substrate or a metal substrate can be used as well. After forming the gate insulating film 3, it is preferable to deposit the oxide semiconductor continuously without exposing the gate insulating film 3 to the air.

Then, pulse light is radiated to the ZnO film that is the oxide semiconductor film 4. The third exemplary embodiment uses an Xe (xenon) flash lamp for this. The radiation light generated by the flash lamp used in this case contains light with wavelength of 200-1500 nm, which can be absorbed by the ZnO film 4. As in FIG. 4B, the light of the flash lamp is radiated towards the ZnO film (oxide semiconductor film) 4. The irradiation area of the pulse light (light of the lamp) is 150 mm×150 mm, and the light is radiated once to the irradiation region. Regarding the irradiation time of the pulse light used in the third exemplary embodiment, the pulse width is set as 1 msec.

As in the case of the first exemplary embodiment described above, the pulse width is not limited to be 1 msec. As in the case of the first exemplary embodiment, the preferable pulse width may be set as appropriate in accordance with the oxide semiconductor film 4 or the substrate 1 to be used.

The irradiation intensity is set as 20 J/cm², for example. This value of the irradiation intensity is presented merely as a way of example, and it is not limited to 20 J/cm². The irradiation intensity may be set as any value as long as it is between the value with which the temperature of the oxide semiconductor film 4 becomes equal to or higher than the peripheral temperature and the value with which the oxide semiconductor film 4 is not crystallized, melted, or sublimated. Further, it is preferable to set the irradiation intensity to be less than the value with which damages to the substrates, such as exfoliation of the oxide semiconductor film 4 from the substrate 1, contraction of the substrate 1, and bending of the substrate 1, do not occur. Specifically, it is preferable to be 0.01-100 J/cm².

However, as in the case of the first exemplary embodiment, the preferable irradiation intensity may be set as appropriate in accordance with the oxide semiconductor film 4 or the substrate to be used.

For the radiated pulse light, it is preferable to contain the wavelength that can be absorbed by the oxide semiconductor. Specifically, it is preferable to contain light with the wavelength of 400 nm or less or the light with the wavelength of 800 nm or higher. As in the case of the first exemplary embodiment, the preferable wavelength of the pulse slight may be set as appropriate in accordance with the oxide semiconductor film 4 or the substrate to be used.

Further, as in the case of the first exemplary embodiment, the preferable irradiation area and the number of irradiations may also be set as appropriate in accordance with the oxide semiconductor film 4 or the substrate to be used.

Next, the ZnO film (oxide semiconductor film) 4 is patterned to a prescribed shape as in the case shown in FIG. 4C. Subsequently, as shown in FIG. 4D, a source/drain metal film is deposited over the gate insulating film 3 and the oxide semiconductor film 4, and the source/drain metal film is patterned to form source/drain electrodes 5.

Thereafter, as shown in FIG. 4E, a silicon oxide film as a protective insulating film 6 is deposited to cover the source/drain electrodes 5 as well as the oxide semiconductor film 4 that is exposed from the source/drain electrodes 5. In order to implement input and output of electric signals, a part of the gate insulating film 3 and the protective insulating film 6 is etched to form an electrode by opening a part of the gate electrode 2 and the source/drain electrodes 5. Thereby, TFT can be fabricated.

Here, the electric properties (drain current-gate voltage properties) of the TFT fabricated without radiating the light of the Xe flash lamp (without pulse light radiation) and the TFT fabricated in the above-described manner by radiating the light of the Xe flash lamp (with pulse light radiation) are compared.

There is an increase of two digits or more in the value of the ON-current (drain current at the gate voltage of 20 V and the drain voltage of 10 V) of the TFT that is obtained by radiating the pulse light (light of the lamp) with respect to the value of the ON-current of the TFT that is obtained without the pulse radiation. Further, the electric property of the TFT with pulse light radiation exhibits a smaller hysteresis characteristic than the electric property of the TFT without pulse light radiation, and has a better performance in the switching property. That is, it is evident that the TFT property is improved when the pulse light is radiated to the oxide semiconductor film.

In the third exemplary embodiment, the pulse light is radiated after forming the oxide semiconductor film 4. However, the present invention is not limited only to such case. The pulse light may be radiated in any steps after forming the oxide semiconductor film 4. For example, the pulse light may be radiated after patterning the oxide semiconductor and forming the source/drain electrodes. Further, the pulse light may be radiated as many times as necessary.

Furthermore, while the third exemplary embodiment has been described by referring to the case of the thin film transistor, the present invention is not limited to such case. The step of radiating the pulse light may be employed when manufacturing thin film diodes and thin film devices such as solar batteries using the oxide semiconductor.

Also, in the third exemplary embodiment, the ZnO film (oxide semiconductor film) 4 after radiating the pulse light is amorphous. This can be verified by conducting an analysis such as X-ray diffraction.

Further, in the thin film device manufacturing steps of the third exemplary embodiment, the temperature of the substrate does not reach up to 150 degrees C. or higher. Because of this, it is possible to use a glass substrate or a resin substrate for the substrate 1.

Other structures and effects thereof are the same as those of the second exemplary embodiment described above.

### Fourth Exemplary Embodiment

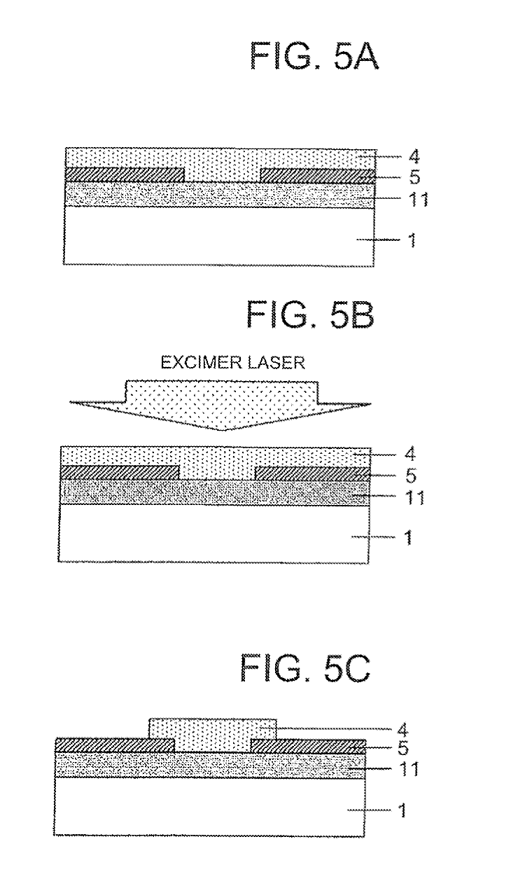

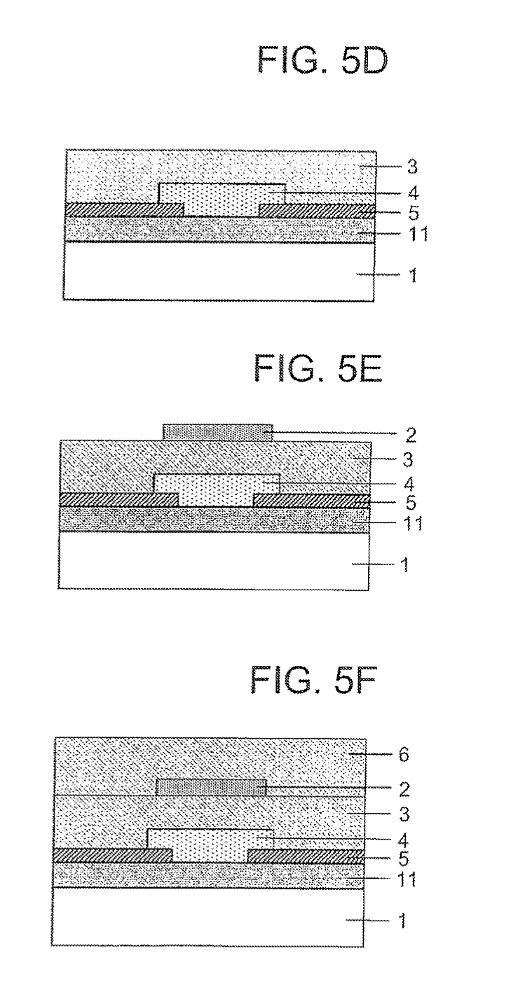

Next, a fourth exemplary embodiment will be described by referring to FIG. 5A-FIG. 5F.

FIG. 5A-FIG. 5F are illustrations of a series of manufacturing steps which can manufacture another TFT (thin film transistor) that is equivalent to the TFT obtained in the first exemplary embodiment described above.

Hereinafter, this will be described.

First, as shown in FIG. 5A, a silicon oxide film is deposited on the insulating substrate 1 as a base insulating film 11. The silicon oxide film is patterned to form source/drain electrodes 5. Thereafter, an oxide semiconductor film (IGZO) 4 is formed on the source/drain electrodes 5 as an active layer.

In the fourth exemplary embodiment, an oxide semiconductor film (IGZO) of 20 nm containing indium, gallium, and zinc is deposited by sputtering as the oxide semiconductor film 4. This IGZO film is amorphous. The sputter target used herein is an IGZO sinter. The composition ratio of the IGZO target is 1:1:1 (indium:gallium:zinc).

In the fourth exemplary embodiment, the oxide semiconductor film formed by using the sputter target having the composition ratio of 1:1:1 (indium:gallium:zinc) is described as the oxide semiconductor film 4. However, the composition ratio is not limited only to that. In addition, while the oxide semiconductor film containing indium, gallium, and zinc is described above as the oxide semiconductor film 4, it is not limited only to such type. An oxide semiconductor such as a ZnO film, which contains at least one element selected from indium, gallium, zinc, and tin, may be used as well.

Further, while the fourth exemplary embodiment is described by using an amorphous oxide semiconductor film as the oxide semiconductor film 4, the present invention is not limited only to such case. It is possible to use a polycrystalline oxide semiconductor film such as a ZnO film or a crystalline oxide semiconductor.

When the oxide semiconductor containing indium, gallium, zinc, and tin is used as the oxide semiconductor film 4, it is possible to form the film at a room temperature. Thus, a resin substrate such as PET, a resin film, a glass substrate, or the like can be used as the substrate 1. Furthermore, a substrate such as a silicon substrate or a metal substrate can be used as well.

After forming the gate insulating film 3, it is preferable to deposit the oxide semiconductor film 4 continuously without exposing the gate insulating film 3 to the air.

Then, pulse light is radiated to the IGZO film that is the oxide semiconductor film 4. In the fourth exemplary embodiment, laser light of 308 nm wavelength generated by the XeCl excimer laser, which can be absorbed by the IGZO film, is radiated towards the IGZO film 4 as in FIG. 5B.

Regarding the irradiation area of the pulse light (laser light generated by the laser), the irradiation time of the pulse light, the pulse width, the irradiation intensity, the wavelength of the pulse light, and the light source of the pulse light, the fourth exemplary embodiment directly employs those used in the first exemplary embodiment described above.

Next, the IGZO film (oxide semiconductor film) 4 to which the pulse light is radiated is patterned to a prescribed shape as in FIG. 5C. Subsequently, as shown in FIG. 5D, a silicon oxide film of 100 nm is deposited on the IGZO film 4 as a gate insulating film 3.

Thereafter, as shown in FIG. 5E, chromium of 100 nm is deposited on the gate insulating film 3, and the chromium is patterned to form a gate electrode 2 on the gate insulating film 3.

Subsequently, as shown in FIG. 5F, a silicon oxide film as a protective insulating film 6 is deposited on the gate electrode 2 to cover the gate electrode 2 with the gate insulating film 6. In order to implement input and output of electric signals, a part of the gate insulating film 3 and the protective insulating film 6 is etched to form an electrode by opening a part of the gate electrode 2 and the source/drain electrodes 5. Thereby, TFT can be fabricated.

Here, the electric properties (drain current-gate voltage properties) of the TFT fabricated without radiating the laser light of the excimer laser (without pulse light radiation) and the TFT fabricated in the above-described manner by radiating the light of the excimer laser (with pulse light radiation) are compared.

There is an increase of two digits or more in the value of the ON-current (drain current at the gate voltage of 20 V and the drain voltage of 10 V) of the TFT that is obtained by radiating the pulse light with respect to the value of the ON-current of the TFT that is obtained without the pulse radiation. Further, the electric property of the TFT with pulse light radiation exhibits a smaller hysteresis characteristic than the electric property of the TFT without pulse light radiation, and has a better performance in the switching property. That is, it is evident that the TFT property is improved when the pulse light is radiated to the oxide semiconductor film 4.

In the fourth exemplary embodiment, the pulse light is radiated after forming the oxide semiconductor film 4. However, the present invention is not limited only to such case. The pulse light may be radiated in any steps after forming the oxide semiconductor. For example, the pulse light may be radiated after patterning the oxide semiconductor film 4 and forming the source/drain electrodes 5. Further, the pulse light may be radiated as many times as necessary.

Furthermore, while the fourth exemplary embodiment has been described by referring to the case of the thin film transistor, the present invention is not limited to such case. The step of irradiating the pulse light may be employed when manufacturing thin film diodes and thin film devices such as solar batteries using the oxide semiconductor film 4.

Also, in the fourth exemplary embodiment, the IGZO film (oxide semiconductor film) 4 after irradiating the pulse light is amorphous. This can be verified by conducting an analysis such as X-ray diffraction.

Further, in the thin film device manufacturing steps of the fourth exemplary embodiment, the temperature of the substrate does not reach up to 150 degrees C. or higher. Because of this, it is possible to use a glass substrate or a resin substrate for the substrate 1. With the fourth exemplary embodiment described above, it is possible to achieve the same effects as those of the first exemplary embodiment described above.

Other structures and effects thereof are the same as those of the first exemplary embodiment described above.

### Fifth Exemplary Embodiment

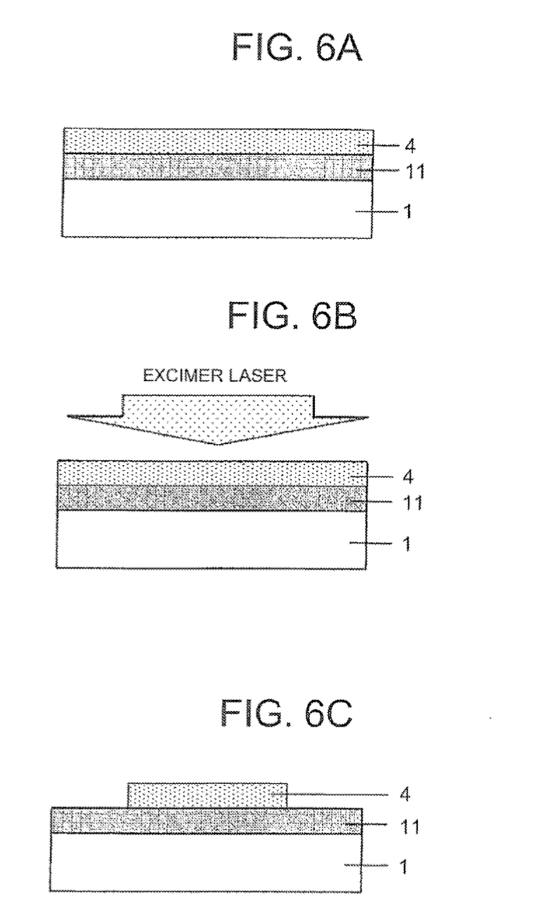

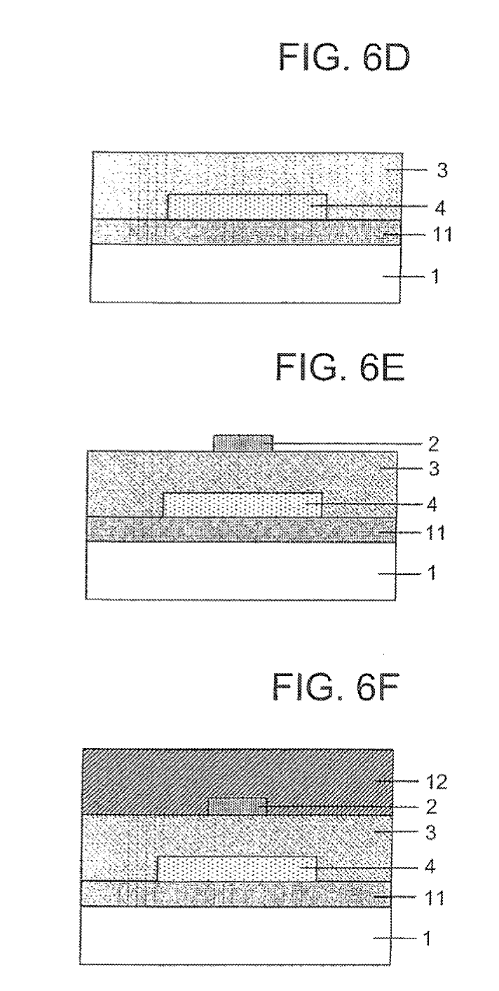

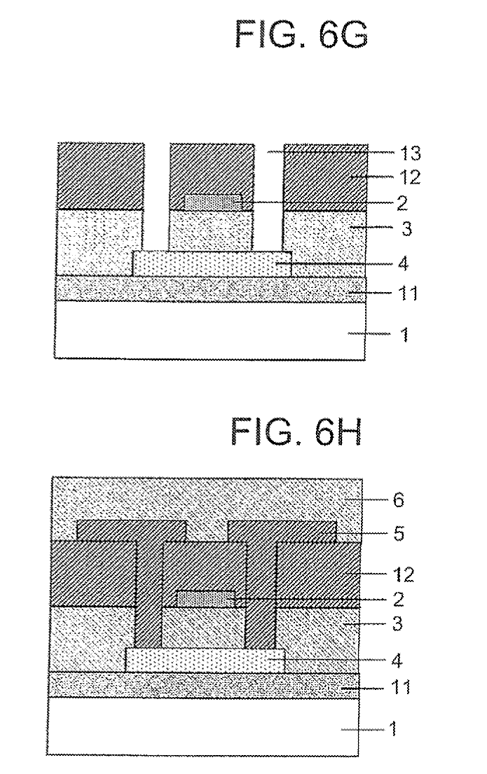

Next, a fifth exemplary embodiment will be described by referring to FIG. 6A-FIG. 6H.

FIG. 6A-FIG. 6H are illustrations of a series of manufacturing steps which can manufacture another TFT (thin film transistor) that is equivalent to the TFT obtained in the first exemplary embodiment described above.

Hereinafter, this will be described.

First, as shown in FIG. 6A, a silicon oxide film is deposited on an insulating substrate 1, and the silicon oxide film is patterned to form a base insulating film 11. Then, an oxide semiconductor film 4 is deposited on the base insulating film 11 as an active layer. In the fifth exemplary embodiment, an oxide semiconductor film (IGZO) of 20 nm containing indium, gallium, and zinc is deposited by sputtering as the oxide semiconductor film 4. This IGZO film (oxide semiconductor film) 4 is amorphous. The sputter target used herein is an IGZO sinter. The composition ratio of the IGZO target is 1:1:1 (indium:gallium:zinc).

The oxide semiconductor film formed by using the sputter target having the composition ratio of 1:1:1 (indium:gallium:zinc) is described as the oxide semiconductor film 4. However, the composition ratio is not limited only to that. In addition, while the oxide semiconductor film containing indium, gallium, and zinc is described above as the oxide semiconductor film 4, it is not limited only to such type. An oxide semiconductor such as a ZnO film, which contains at least one element selected from indium, gallium, zinc, and tin may be used as well.

Further, while the fifth exemplary embodiment is described by using the amorphous oxide semiconductor film as the oxide semiconductor film 4, the present invention is not limited only to such case. As the amorphous oxide semiconductor film 4, it is possible to use a polycrystalline oxide semiconductor film such as a ZnO film or a crystalline oxide semiconductor. When the oxide semiconductor containing indium, gallium, zinc, and tin is used as the oxide semiconductor film 4, it is possible to form the film at a room temperature. Thus, a resin substrate such as PET, a resin film, a glass substrate, or the like can be used as the substrate 1. Furthermore, a substrate such as a silicon substrate or a metal substrate can also be used as the material for the substrate 1.

Further, after forming the gate insulating film 11, it is preferable to deposit the oxide semiconductor film 4 continuously so without exposing the base gate insulating film 11 to the air.

Then, pulse light is radiated to the IGZO film that is the oxide semiconductor film 4. In the fifth exemplary embodiment, laser light of 308 nm wavelength generated by the XeCl excimer laser, which can be absorbed by the IGZO film, is radiated towards the IGZO film 4 as in FIG. 6B.

Regarding the irradiation area of the pulse light (laser light generated by the laser), the irradiation time of the pulse light, the pulse width, the irradiation intensity, the wavelength of the pulse light, and the light source of the pulse light, the fifth exemplary embodiment directly employs those used in the first exemplary embodiment described above.

Next, the IGZO film (oxide semiconductor film) 4 to which the pulse light is radiated is patterned to a prescribed shape as in FIG. 6C. Subsequently, as shown in FIG. 6D, a silicon oxide film of 100 nm is deposited on the IGZO film 4, and the silicon oxide film is patterned to form a gate insulating film 3.

Thereafter, as shown in FIG. 6E, chromium is deposited on the gate insulating film 3, and the chromium is patterned to form a gate electrode 2. Then, as shown in FIG. 6F, a silicon oxide film as an interlayer insulating film 12 is deposited on the gate electrode 2 and the gate insulating film 3. Subsequently, as shown in FIG. 6G, contact holes 13 for the source/drain electrodes are formed.

Then, as shown in FIG. 6H, a metal film is filled inside the contact holes 13 to form source/drain electrodes 5 which are connected to the IGZO film 4. Thereafter, a silicon oxide film is deposited on the source/drain electrodes 5 and the interlayer insulating film 12 as a protective insulating film 6. Thereby, TFT can be fabricated.

Here, the electric properties (drain current-gate voltage properties) of the TFT fabricated without radiating the laser light (pulse light) of the excimer laser (without pulse light radiation) and the TFT fabricated in the above-described manner by radiating the laser light of the excimer laser (with pulse light radiation) are compared.

There is an increase of two digits or more in the value of the ON-current (drain current at the gate voltage of 20 V and the drain voltage of 10 V) of the TFT that is obtained by radiating the pulse light with respect to the value of the ON-current of the TFT that is obtained without the pulse radiation.

Further, the electric property of the TFT with pulse light radiation exhibits a smaller hysteresis characteristic than the electric property of the TFT without pulse light radiation, and has a better performance in the switching property. That is, it is evident that the TFT property is improved when the pulse light is radiated to the oxide semiconductor film 4.

In the fifth exemplary embodiment, the pulse light is radiated after forming the oxide semiconductor film 4. However, the present invention is not limited only to such case. The pulse light may be radiated in any steps after forming the oxide semiconductor film 4. For example, the pulse light may be radiated after patterning the oxide semiconductor film 4 and forming the source/drain electrodes 5. Further, the pulse light may be radiated as many times as necessary.

Furthermore, while the fifth exemplary embodiment has been described by referring to the case of the thin film transistor, the present invention is not limited to such case. The step of radiating the pulse light may be employed when manufacturing thin film diodes and thin film devices such as solar batteries using the oxide semiconductor film. Also, in the fifth exemplary embodiment, the IGZO film (oxide semiconductor film) 4 after radiating the pulse light is amorphous. This can be verified by conducting an analysis such as X-ray diffraction.

Further, in the thin film device manufacturing steps of the fifth exemplary embodiment, the temperature of the substrate does not reach up to 150 degrees C. or higher. Because of this, it is possible to use a glass substrate or a resin substrate for the substrate.

Other structures and effects thereof are the same as those of the first exemplary embodiment described above.

### Sixth Exemplary Embodiment

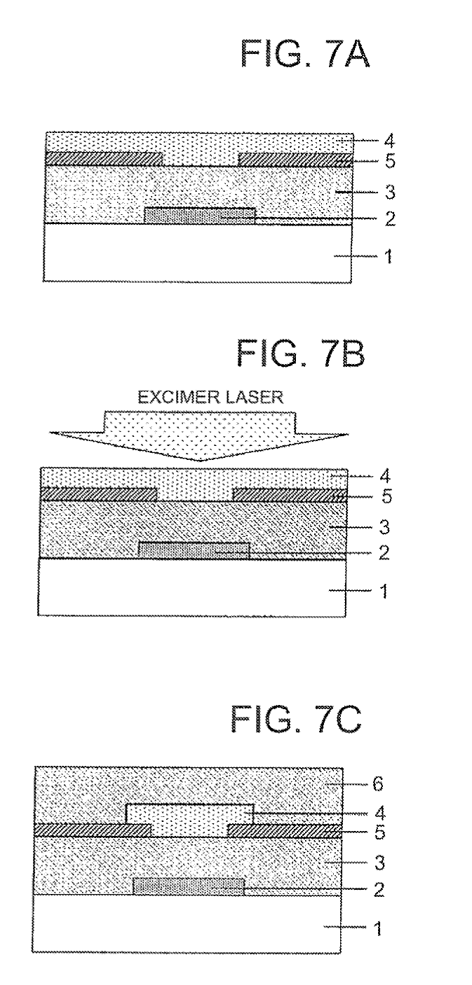

Next, a sixth exemplary embodiment will be described by referring to FIG. 7.

FIG. 7 of the sixth exemplary embodiment shows illustrations of a series of manufacturing steps which can manufacture another TFT that is equivalent to the TFT (thin film transistor) obtained in the first exemplary embodiment described above.

Hereinafter, this will be described.

First, as shown in FIG. 7A, chromium is deposited on an insulating substrate 1, and the chromium is patterned to form a gate electrode 2. Thereafter, a gate insulating film 3 is deposited on the gate electrode 2 and the substrate 1. Then, a metal film is deposited on the gate insulating film 3, and the metal film is patterned to form source/drain electrodes 5. Thereafter, an oxide semiconductor film 4 is deposited on the source/drain electrodes 5 as an active layer.

Here, an oxide semiconductor film (IGZO) of 20 nm containing indium, gallium, and zinc is deposited by sputtering as the oxide semiconductor film 4. This IGZO film is amorphous. The sputter target used herein is an IGZO sinter. The composition ratio of the IGZO target is 1:1:1 (indium:gallium:zinc).

The oxide semiconductor film formed by using the sputter target having the composition ratio of 1:1:1 (indium:gallium:zinc) is described as the oxide semiconductor film 4. However, the composition ratio is not limited only to that. In addition, while the oxide semiconductor film containing indium, gallium, and zinc is described above as the material of the oxide semiconductor film 4, it is not limited only to such case. An oxide semiconductor such as a ZnO film, which contains at least one element selected from indium, gallium, zinc, and tin, may be used as well.

Further, while the sixth exemplary embodiment is described by using an amorphous oxide semiconductor film as the oxide semiconductor film 4, the present invention is not limited only to such case. It is possible to use a polycrystalline oxide semiconductor film such as a ZnO film or a crystalline oxide semiconductor as the material.

When the oxide semiconductor containing indium, gallium, zinc, and tin is used as the oxide semiconductor film 4, it is possible to form the film at a room temperature. Thus, a resin substrate such as PET, a resin film, a glass substrate, or the like can be used as the substrate 1. Furthermore, a substrate such as a silicon substrate or a metal substrate can be used as well. Further, after forming the gate insulating film 3, it is preferable to deposit the oxide semiconductor film 4 continuously without exposing the base gate insulating film 3 to the air.

Then, pulse light is radiated to the IGZO film that is the oxide semiconductor film 4. In the sixth exemplary embodiment, laser light of 308 nm wavelength generated by the XeCl excimer laser, which can be absorbed by the IGZO film, is radiated towards the IGZO film 4 as in FIG. 7B.

Regarding the irradiation area of the pulse light (the laser light), the irradiation time of the pulse light, the pulse width, the irradiation intensity, the wavelength of the pulse light, and the light source of the pulse light, the sixth exemplary embodiment directly employs those used in the first exemplary embodiment described above.

Next, the IGZO film (oxide semiconductor film) 4 is patterned to a prescribed shape as in FIG. 7C. Subsequently, a protective insulating film 6 is deposited on the IGZO film 4 to which the pulse light has been radiated. In order to implement input and output of electric signals, a part of the gate insulating film 3 and the protective insulating film 6 is etched to form an electrode by opening a part of the gate electrode 2 and the source/drain electrodes 5. Thereby, TFT can be fabricated.

Here, the electric properties (drain current-gate voltage properties) of the TFT fabricated without radiating the laser light of the excimer laser (without pulse light radiation) and the TFT fabricated in the above-described manner by radiating the light of the excimer laser (with pulse light radiation) are compared. There is an increase of two digits or more in the value of the ON-current (drain current at the gate voltage of 20 V and the drain voltage of 10 V) of the TFT that is obtained by radiating the pulse light with respect to the value of the ON-current of the TFT that is obtained without the pulse radiation. Further, the electric property of the TFT with pulse light radiation exhibits a smaller hysteresis characteristic than the electric property of the TFT without pulse light radiation, and has a better performance in the switching property. That is, it is evident that the TFT property is improved when the pulse light is radiated to the oxide semiconductor film 4.

In the sixth exemplary embodiment, the pulse light is radiated after forming the oxide semiconductor film 4. However, the present invention is not limited only to such case. The pulse light may be radiated in any steps after forming the oxide semiconductor film 4. For example, the pulse light may be radiated after patterning the oxide semiconductor film 4 and forming the source/drain electrodes 5. Further, the pulse light may be radiated as many times as necessary.

Furthermore, while the sixth exemplary embodiment has been described by referring to the case of the thin film transistor, the present invention is not limited to such case. The step of radiating the pulse light may be employed when manufacturing thin film diodes and thin film devices such as solar batteries using the oxide semiconductor films 4.

Also, in the sixth exemplary embodiment, the IGZO film (oxide semiconductor film) 4 after radiating the pulse light keeps the amorphous state for all the used materials. This can be verified by conducting an analysis such as X-ray diffraction.

Further, in the thin film device manufacturing steps of the sixth exemplary embodiment, the temperature of the substrate does not reach up to 150 degrees C. or higher. Because of this, it is possible to use a glass substrate or a resin substrate for the substrate 1.

Other structures and effects thereof are the same as those of the first exemplary embodiment described above.

### Seventh Exemplary Embodiment

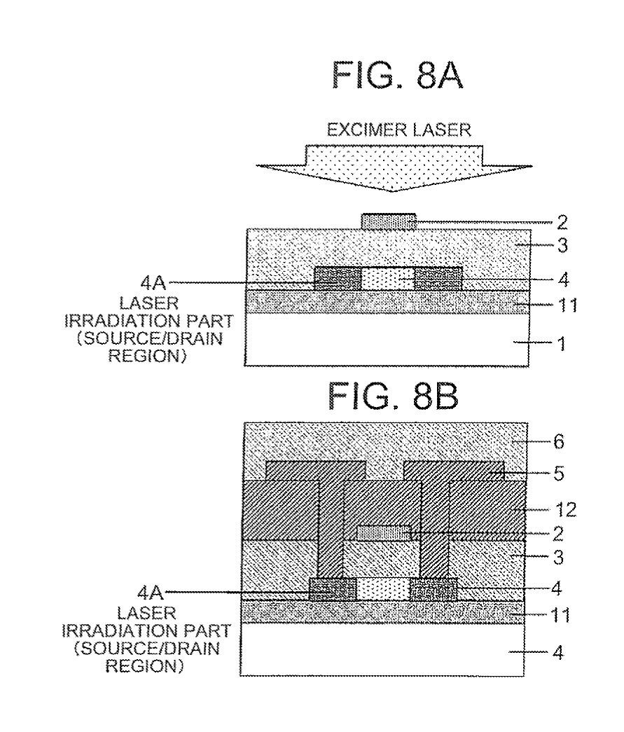

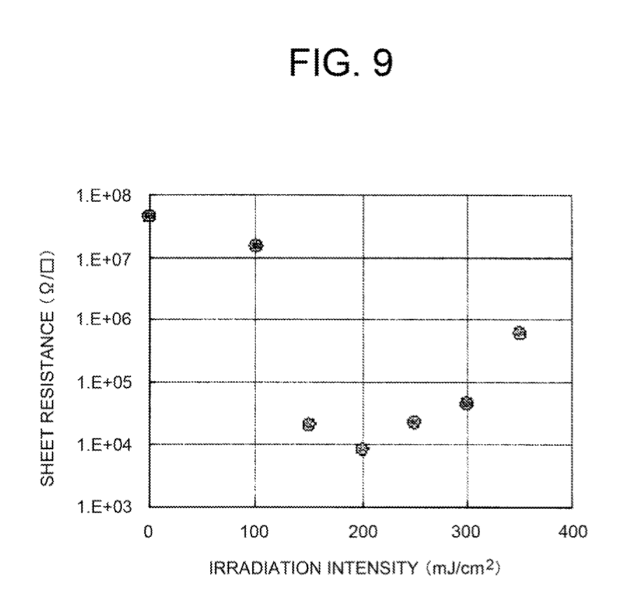

Next, a seventh exemplary embodiment will be described by referring to FIG. 8-FIG. 9.

FIG. 8-FIG. 9 of the seventh exemplary embodiment are illustrations of a series of manufacturing steps which can manufacture another TFT that is equivalent to the TFTs (thin film transistors) obtained in each of the first-fifth exemplary embodiments described above.

Hereinafter, this will be described.

First, as shown in FIG. 8A; a base insulating film 11 is deposited on an insulating substrate 1. Thereafter, an oxide semiconductor film 4 is patterned as an active layer, and it is deposited on the base insulating film 11.

In the seventh exemplary embodiment, an oxide semiconductor film (IGZO) of 20 nm containing indium, gallium, and zinc is deposited by sputtering as the oxide semiconductor film 4. This IGZO film is amorphous. The sputter target used herein is an IGZO sinter. The composition ratio of the IGZO target is 1:1:1 (indium:gallium:zinc).

While the oxide semiconductor film formed by using the sputter target (IGZO) having the composition ratio of 1:1:1 (indium:gallium:zinc) is described as the oxide semiconductor film, it is merely presented as a way of example. The composition ratio is not limited only to that. In addition, while the oxide semiconductor film containing indium, gallium, and zinc is described above as the oxide semiconductor film 4, it is not limited only to such type. An oxide semiconductor such as a ZnO film, which contains at least one element selected from indium, gallium, zinc, and tin, may be used as well.

Further, while the seventh exemplary embodiment is described by using the amorphous oxide semiconductor film as the oxide semiconductor film 4, the present invention is not limited only to such case. As the material for the amorphous oxide semiconductor film 4, it is possible to use a polycrystalline oxide semiconductor film such as a ZnO film or a crystalline oxide semiconductor. When the oxide semiconductor containing indium, gallium, zinc, and tin is used as the oxide semiconductor film 4, it is possible to form the film at a room temperature. Thus, a resin substrate such as PET, a resin film, a glass substrate, or the like can be used as the substrate 1. Furthermore, a substrate such as a silicon substrate or a metal substrate can be used as well.

Further, after forming the gate insulating film 11, it is preferable to deposit the oxide semiconductor film 4 continuously without exposing the base gate insulating film 11 to the air.

Then, a gate insulating film 3 is deposited on the IGZO film 4. Thereafter, a gate electrode 2 is formed on the gate insulating film 3 by performing patterning. Subsequently, as shown in FIG. 8A, pulse light is radiated towards the IGZO film 4 through the gate insulating film 3. In the seventh exemplary embodiment, laser light of 308 nm wavelength generated by an XeCl excimer laser, which can be absorbed by the IGZO film 4, is radiated. This laser light corresponds to the pulse light.

Through forming the gate electrode 2 with a film having high reflectance or a film having high absorption rate with respect to the pulse light, it is possible to radiate the pulse light (the laser light) to the oxide semiconductor film 4 that is exposed towards the outer side from the gate electrode 2 and not to radiate the pulse light (laser light) to the oxide semiconductor film 4 located directly beneath the gate electrode 2.

In regions (laser irradiate regions) 4A of the IGZO film 4 to which the laser light has been radiated, resistance becomes deteriorated. When TFT is fabricated by having such regions source/drain regions 4A, it is possible to reduce the resistance of the source/drain regions 4A and to reduce the contact resistance between the source/drain electrodes and the source/drain regions 4A. Therefore, the ON-current of the TFT can be improved.

Regarding the irradiation area of the pulse light (the laser), the irradiation time of the pulse light, the pulse width, the irradiation intensity, the wavelength of the pulse light, and the light source of the pulse light, the seventh exemplary embodiment directly employs those used in the first exemplary embodiment described above.

Subsequently, as shown in FIG. 8B, an interlayer insulating film 12 is formed on the gate insulating film 3 and the gate electrode 2. Thereafter, a part of the gate insulating film 3 and the interlayer insulating film 12 is etched to form contact holes, and a metal film is filled into the contact holes to form source/drain electrodes 5 Which are connected to the source/drain regions 4. Then, a protective insulating film 6 is formed on the interlayer insulating film 12 to cover the source/drain electrodes 5.

Here, the electric properties (drain current-gate voltage properties) of the TFT fabricated without radiating the laser light of the excimer laser (without pulse light radiation) to the source/drain regions and the TFT fabricated in the above-described manner by radiating the light of the excimer laser (with pulse light radiation) are compared.

There is an increase of twice in the value of the ON-current (drain current at the gate voltage of 20 V and the drain voltage of 10 V) of the TFT that is obtained by radiating the pulse light with respect to the value of the ON-current of the TFT that is obtained without the pulse radiation. That is, it is evident that the TFT property is improved when the pulse light is radiated to the source/drain regions 4A of the oxide semiconductor film 4.

FIG. 9 shows sheet resistance of the IGZO film (20 nm) for the irradiation intensity of the laser light irradiated by the excimer laser. The irradiation intensity “0” is the sheet resistance of the IGZO film to which no laser light is radiated. It is found that the sheet resistance varies according to the irradiation intensity, and it is evident that prescribed resistance of the source/drain regions 4 can be achieved by controlling the irradiation intensity.

In the seventh exemplary embodiment, the pulse light is radiated after forming the gate electrode 2. However, the present invention is not limited only to such case. The pulse light may be radiated in any steps after forming the oxide semiconductor. Further, the pulse light may be radiated as many times as necessary.

Furthermore, while the seventh exemplary embodiment has been described by referring to the case of the thin film transistor, the present invention is not limited to such case. The step of radiating the pulse light may be employed when manufacturing thin film diodes and thin film devices such as solar batteries using the oxide semiconductor.

Also, in the seventh exemplary embodiment, the IGZO film (oxide semiconductor film) 4 after radiating the pulse light is amorphous. This can be verified by conducting an analysis such as X-ray diffraction.

Further, in the thin film device manufacturing steps of the seventh exemplary embodiment, the temperature of the substrate 1 does not reach up to 150 degrees C. or higher. Because of this, it is possible to use a glass substrate or a resin substrate for the substrate 1.

Other structures and effects thereof are the same as those of the fifth exemplary embodiment described above.

### Eighth Exemplary Embodiment

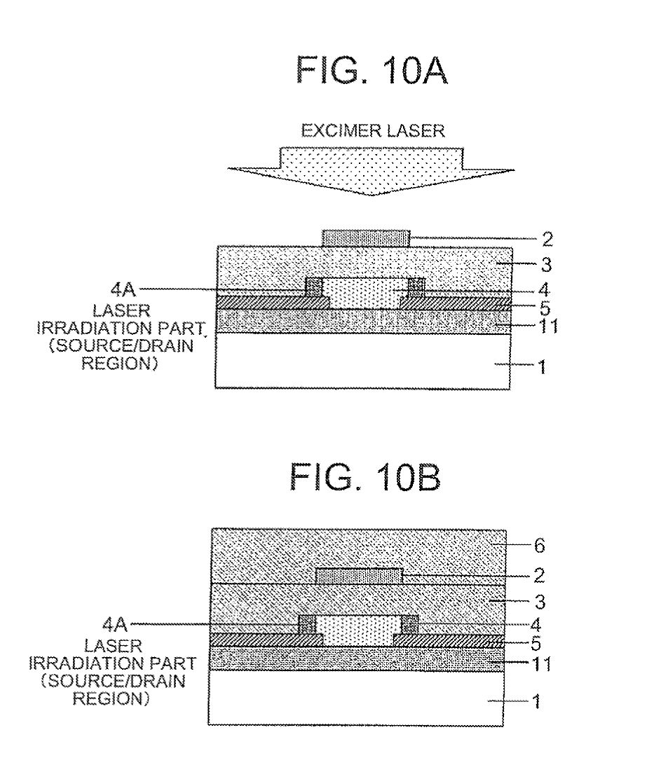

Next, an eighth exemplary embodiment will be described by referring to FIG. 10.

FIG. 10 of the eighth exemplary embodiment shows illustrations of a series of manufacturing steps which can manufacture another TFT that is equivalent to the TFT (thin film transistors) obtained in the first exemplary embodiment described above.

Hereinafter, this will be described.

First, as shown in FIG. 10A, after forming a base insulating film 11 on an insulating substrate 1, source/drain electrodes 5 are patterned and formed on the base insulating film 11. An oxide semiconductor film 4 is patterned as an active layer, and it is deposited on the source/drain electrodes 5.

In the eighth exemplary embodiment, an oxide semiconductor film (IGZO) of 20 nm containing indium, gallium, and zinc is deposited by sputtering as the oxide semiconductor film 4. This IGZO film is amorphous. The sputter target used herein is an IGZO sinter.

The composition ratio of the IGZO target is set as 1:1:1 (indium:gallium:zinc). While the oxide semiconductor film formed by using the sputter target having the composition ratio of 1:1:1 (indium:gallium:zinc) is described as the oxide semiconductor film 4, it is merely presented as a way of example. The composition ratio is not limited only to that. In addition, while the oxide semiconductor film containing indium, gallium, and zinc is described above as the oxide semiconductor film 4, it is not limited only to such type. An oxide semiconductor such as a ZnO film, which contains at least one element selected from indium, gallium, zinc, and tin, may be used as well.

Further, while the eighth exemplary embodiment is described by using an amorphous oxide semiconductor film as the oxide semiconductor film 4, the present invention is not limited only to such case. As the material, it is possible to use a polycrystalline oxide semiconductor film such as a ZnO film or a crystalline oxide semiconductor. When the oxide semiconductor containing indium, gallium, zinc, and tin is used as the oxide semiconductor film 4, it is possible to form the film at a room temperature. Thus, a resin substrate such as PET, a resin film, a glass substrate, or the like can be used as the substrate 1. Furthermore, a substrate such as a silicon substrate or a metal substrate can be used as well.

Subsequently, a gate insulating film 3 is deposited to cover the source/drain electrodes 5 and the IGZO film 4 (including the source/drain regions 4A) with the gate insulating film 3. Thereafter, a gate electrode 2 is patterned and formed on the gate insulating film 3. Subsequently, as shown in FIG. 10A, pulse light is radiated. In the eighth exemplary embodiment, laser light of 308 nm wavelength generated by an XeCl excimer laser, which can be absorbed by the IGZO film, is radiated.

Through forming the gate electrode 2 with a film having high reflectance or a film having high absorption rate with respect to the pulse light, it is possible to radiate the pulse light to the oxide semiconductor film 4 that is exposed towards the outer side from the gate electrode 2 and not to radiate the pulse light to the oxide semiconductor film 4 located directly beneath the gate electrode 2.

In the regions (laser irradiate regions) 4A of the IGZO film 4 to which the laser has been radiated, resistance becomes deteriorated. When TFT is fabricated by having such regions as source/drain regions 4A, it is possible to reduce the resistance of the source/drain regions 4A and to reduce the contact resistance between the source/drain electrodes 5 and the source/drain regions 4A. Therefore, the ON-current of the TFT can be improved.

Regarding the irradiation area of the pulse light (the laser light), the irradiation time of the pulse light, the pulse width, the irradiation intensity, the wavelength of the pulse light, and the light source of the pulse light, the eighth exemplary embodiment directly employs those used in the first exemplary embodiment described above.

Subsequently, as shown in FIG. 10B, a protective insulating film 6 is deposited to cover the gate electrode 2. In order to implement input and output of electric signals, a part of the gate insulating film 3 and the protective insulating film 6 is etched to form an electrode by opening a part of the gate electrode 2 and the source/drain electrodes 5. Thereby, TFT can be fabricated.

Here, the electric properties (drain current-gate voltage properties) of the TFT fabricated without radiating the laser light of the excimer laser (without pulse light radiation) to the source/drain regions 4A and the TFT fabricated in the above-described manner by radiating the light of the excimer laser (with pulse light radiation) are compared. There is an increase of twice in the value of the ON-current (drain current at the gate voltage of 20 V and the drain voltage of 10 V) of the TFT that is obtained by radiating the pulse light with respect to the value of the ON-current of the TFT that is obtained without the pulse radiation. That is, it is evident that the TFT property is improved when the pulse light is radiated to the source/drain regions 4A of the oxide semiconductor film 4.

In the eighth exemplary embodiment, the pulse light is radiated after forming the gate electrode 2. However, the present invention is not limited only to such case. The pulse light may be radiated in any steps after forming the oxide semiconductor film 4. Further, the pulse light may be radiated as many times as necessary.

Furthermore, while the eighth exemplary embodiment has been described by referring to the case of the thin film transistor, the present invention is not limited to such case. The step of radiating the pulse light may be employed when manufacturing thin film diodes and thin film devices such as solar batteries using the oxide semiconductor.

Also, in the eighth exemplary embodiment, the IGZO film (oxide semiconductor film) 4 after radiating the pulse light is amorphous. This can be verified by conducting an analysis such as X-ray diffraction.

Further, in the thin film device manufacturing steps of the eighth exemplary embodiment, the temperature of the substrate 1 does not reach up to 150 degrees C. or higher. Because of this, it is possible to use a glass substrate or a resin substrate for the substrate 1.

Other structures and effects thereof are the same as those of the first exemplary embodiment described above.

### Ninth Exemplary Embodiment

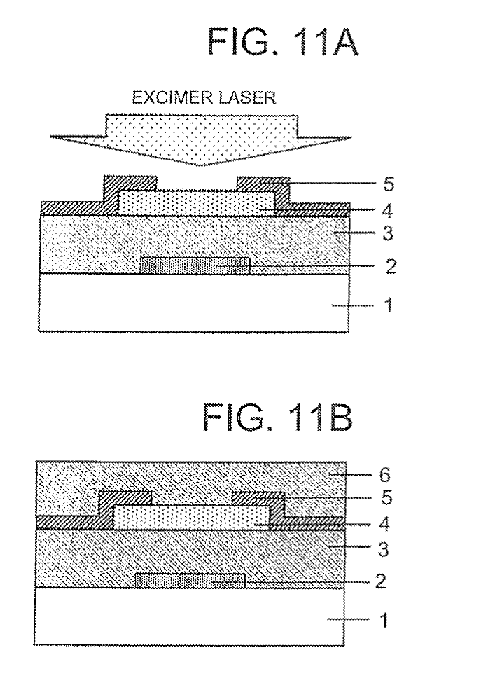

Next, a ninth exemplary embodiment will be described by referring to FIG. 11.

FIG. 11 of the ninth exemplary embodiment shows illustrations of a series of manufacturing steps which can manufacture another TFT that is equivalent to the TFT (thin film transistors) obtained in the first exemplary embodiment described above.

Hereinafter, this will be described.

First, as shown in FIG. 11 A, after forming a patterned gate electrode 2 on n insulating substrate 1, a gate insulating film 3 for covering the gate electrode 2 is deposited. Then, an oxide semiconductor film 4 is deposited on the gate insulating film 3 as an active layer. In the ninth exemplary embodiment, an oxide semiconductor film (IGZO) of 20 nm containing indium, gallium, and zinc is deposited by sputtering as the oxide semiconductor film 4. This IGZO film is amorphous.

The sputter target used herein is an IGZO sinter. The composition ratio of the IGZO target is 1:1:1 (indium:gallium:zinc). The oxide semiconductor film formed by using the sputter target having the composition ratio of 1:1:1 (indium:gallium:zinc) is described as the oxide semiconductor film 4. However, the composition ratio is not limited only to that. In addition, while the oxide semiconductor film containing indium, gallium, and zinc is described above as the oxide semiconductor film 4, the present invention is not limited only to such type. An oxide semiconductor such as a ZnO film, which contains at least one element selected from indium, gallium, zinc, and tin may be used as well.

Further, while the ninth exemplary embodiment is described by using an amorphous oxide semiconductor film as the oxide semiconductor film 4, the present invention is not limited only to such case. It is possible to use a polycrystalline oxide semiconductor film such as a ZnO film or a crystalline oxide semiconductor as the material.

When the oxide semiconductor containing indium, gallium, zinc, and tin is used as the oxide semiconductor film 4, it is possible to form the film at a room temperature. Thus, a resin substrate such as PET, a resin film, a glass substrate, or the like can be used as the substrate 1. Furthermore, a substrate such as a silicon substrate or a metal substrate can be used as well. Further, after forming the gate insulating film 3, it is preferable to deposit the oxide semiconductor film 4 continuously without exposing the base gate insulating film 3 to the air.

Then, the oxide semiconductor 4 is patterned. Thereafter, a metal film is deposited on the oxide semiconductor 4, and the metal film is patterned to form source/drain electrodes 5 by surrounding the oxide semiconductor 4.

Subsequently, as shown in FIG. 11A, pulse light is radiated to the IGZO film 4 that is the oxide semiconductor film exposed from the source/drain electrodes 5. In the ninth exemplary embodiment, as in the case of FIG. 2, laser light of 308 nm wavelength generated by an XeCl excimer laser, which can be absorbed by the IGZO film, is radiated towards the oxide semiconductor film 4 that is the IGZO film.

Regarding the irradiation area of the pulse light (the laser light), the irradiation time of the pulse light, the pulse width, the irradiation intensity, the wavelength of the pulse light, and the light source of the pulse light, the ninth exemplary embodiment directly employs those used in the first exemplary embodiment described above.

Subsequently, as shown in FIG. 11B, a protective insulating film 6 is deposited to cover the source/drain electrodes 5 and the IGZO film 4. In order to implement input and output of electric signals, a part of the gate insulating film 3 and the protective insulating film 6 is etched to form an electrode by opening a part of the gate electrode 2 and the source/drain electrodes 5. Thereby, TFT can be fabricated.

Here, the electric properties (drain current-gate voltage properties) of the TFT fabricated without radiating the laser light of the excimer laser (without pulse light radiation) and the TFT fabricated in the above-described manner by radiating the light of the excimer laser (with pulse light radiation) are compared. There is an increase of two digits or more in the value of the ON-current (drain current at the gate voltage of 20 V and the drain voltage of 10 V) of the TFT that is obtained by radiating the pulse light with respect to the value of the ON-current of the TFT that is obtained without the pulse radiation. Further, the electric property of the TFT with pulse light radiation exhibits a smaller hysteresis characteristic than the electric property of the TFT without pulse light radiation, and has a better performance in the switching property. That is, it is evident that the TFT property is improved when the pulse light is radiated to the oxide semiconductor film.

In the ninth exemplary embodiment, the pulse light is radiated after forming the source/drain electrodes 5. However, the present invention is not limited only to such case. The pulse light may be radiated in any steps after forming the oxide semiconductor film 4. Further, the pulse light may be radiated as many times as necessary.

While the ninth exemplary embodiment has been described by referring to the case of the thin film transistor, the present invention is not limited to such case. The step of radiating the pulse light may be employed when manufacturing thin film diodes and thin film devices such as solar batteries using the oxide semiconductor film.

Also, in the ninth exemplary embodiment, the IGZO film after radiating the pulse light is amorphous. This can be verified by conducting an analysis such as X-ray diffraction

Further, in the thin film device manufacturing steps of the ninth exemplary embodiment, the temperature of the substrate 1 does not reach up to 150 degrees C. or higher. Because of this, it is possible to use a glass substrate or a resin substrate for the substrate 1.

Other structures and effects thereof are the same as those of the first exemplary embodiment described above.

### Tenth Exemplary Embodiment

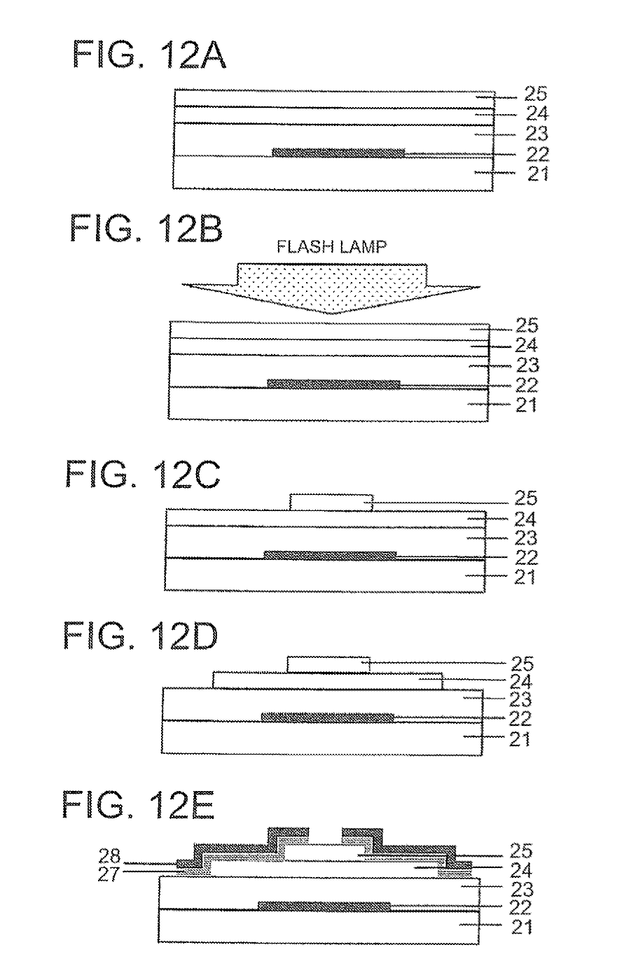

Next, a tenth exemplary embodiment will be described by referring to FIG. 12.

FIG. 12 of the tenth exemplary embodiment are illustrations of a series of manufacturing steps which can manufacture another TFT that is equivalent to the TFTs (thin film transistors) obtained in the first exemplary embodiment described above.

Hereinafter, this will be described.

First, as shown in FIG. 12A, chromium of 100 nm is deposited on a glass substrate 21 as a gate electrode 22, and it is patterned to the shape of the gate electrode 22. Subsequently, a first silicon oxide film (gate insulating film) 23, an amorphous film (amorphous IGZO film) 24 made with an oxide of indium, gallium, and zinc, and a second silicon oxide film (channel protective film) 25 are deposited in a stacked manner by sputtering.

Note here that the film thickness of the gate insulating film (the first silicon oxide film) 23 is 300 nm. The amorphous IGZO film 24 functions as a semiconductor active layer, and the film thickness thereof is 20 nm. The second silicon oxide film (channel protective film) 25 functions as a channel protective film, and the film thickness thereof is 100 nm. Further, in order to reduce the defect density at the interfaces, it is desirable for each of those stacked films to be formed continuously without being exposed to the air.

Subsequently, as shown in FIG. 12B, pulse light emitted from an Xe flash lamp is radiated over the whole surface of the substrate 21 from the above the second silicon oxide film (channel protective film) 25 to execute single pulse light annealing. The pulse irradiation time per pulse is 1 msec, and the total irradiation energy density is 1 J/cm². The pulse irradiation intensity with respect to the irradiation time may change in a form close to a rectangular shape (the light intensity rises and falls in a short time) or may be in a form close to a triangular wave (the light intensity rises and falls gradually).

In the tenth exemplary embodiment, the pulse light is radiated in a state where the amorphous IGZO film 24 is sandwiched between the silicon oxide films having smaller thermal conductivity, i.e., the gate insulating film (the first silicon oxide film) 23 and the second silicon oxide film (channel protective film) 25. Therefore, the amorphous IGZO film 24 that has absorbed the light is heated efficiently in a short time, and a desired structural change can be achieved.

Thereafter, as shown in FIG. 12C, the second silicon oxide film (channel protective film) 25 is patterned. As the methods for this patterning, there are dry etching using plasma and wet etching using a solution containing fluoride. The structure of the amorphous IGZO film 24 is improved by the pulse light annealing processing described above. Thereby, the chemical coupling between the adhesives can be made stronger, so that the resistance to the etching can be improved.

Therefore, the etching selection ratio with respect to the second silicon oxide film (channel protective film) 25 becomes larger for both cases with the dry etching and wet etching, so that only the second silicon oxide film (channel protective film) 25 can be etched selectively.

Subsequently, as shown in FIG. 12D, the amorphous IGZO film 24 is patterned to a desired island shape by dry or wet etching.

Further, as shown in FIG. 12E, a stacked film of an ITO film 27 and a meal film 28 for forming source/drain electrodes is deposited. It is desirable to deposit the ITO film 27 first, so that the amorphous IGZO film 24 comes in contact with the ITO film 27. Thereafter, this stacked film is etched to be patterned to a desired source/drain shapes.

At last, a third silicon oxide film (not shown) is deposited as a passivation film. In order to implement input and output of electric signals, a part of the gate insulating film 23 and the protective insulating film 25 is etched to form an electrode by opening a part of the gate electrode 22 and the source/drain electrodes (ITO film) 27. Thereby, the thin film transistor can be completed.

In the tenth exemplary embodiment, annealing using the pulse light is executed after forming the second silicon oxide film (channel protective film) 25. However, the annealing may be performed at any point and as many times as necessary as long as it is executed after forming the amorphous IGZO film 24.

For example, when pulse light annealing is performed after depositing the last passivation silicon oxide film in addition to the pulse light annealing performed after depositing the second silicon oxide film (channel protective film) 25, effects such as obtaining high-quality passivation silicon oxide film and reduction of the contact resistance in the source/drain regions formed by coupling the amorphous IGZO film 24 and the ITO film 27 can be expected due to the annealing effect.

Further, the pulse light annealing is not limited to be executed with the single pulse, but may be executed with radiations of a plurality of pulses, e.g., radiations of ten pulses at 10 Hz.

Further, while the tenth exemplary embodiment is described by referring to case of the amorphous oxide semiconductor film, the present invention is,not limited only to such case. It is possible to use a polycrystalline oxide semiconductor film such as a ZnO film or a crystalline oxide semiconductor. When the oxide semiconductor containing indium, gallium, zinc, and tin is used as the oxide semiconductor film 24, it is possible to form the film at a room temperature. Thus, a resin substrate such as PET, a resin film, a glass substrate, or the like can be used as the substrate 21. Furthermore, a substrate such as a silicon substrate or a metal substrate can be used as well.

Other structures and effects thereof are the same as those of the first exemplary embodiment described above.

### Eleventh Exemplary Embodiment

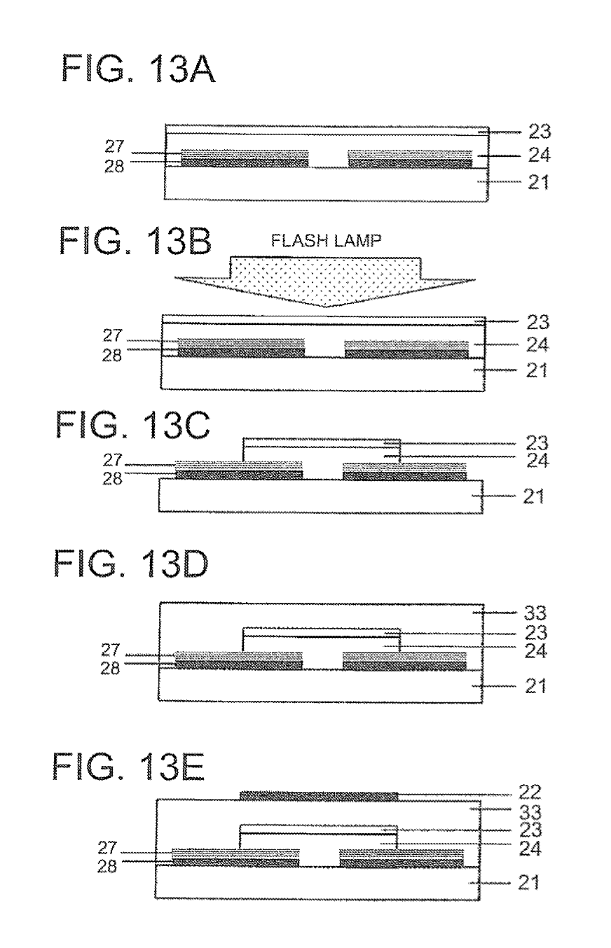

Next, an eleventh exemplary embodiment will be described by referring to FIG. 13.

FIG. 13 of the eleventh exemplary embodiment shows illustrations of a series of manufacturing steps which can manufacture another TFT that is equivalent to the TFTs (thin film transistors) obtained in the first exemplary embodiment described above.

Hereinafter, this will be described.

Note here that same reference numerals are applied to same structural members as those of the tenth exemplary embodiment described above.

First, as shown in FIG. 13A, a stacked film of a metal film 28 and an ITO film 27 for forming source/drain electrodes is deposited on a glass substrate 21. In this case, the metal film 28 is deposited first. Thereafter, this stacked film is etched and patterned to desired source/drain shapes.

Subsequently, an amorphous IGZO film (oxide semiconductor film) 24 and a first silicon oxide film (gate insulating film) 23 are deposited in a stacked manner by sputtering. Note here that the amorphous IGZO film 24 functions as a semiconductor active layer, and the film thickness thereof is 30 nm. The first silicon oxide film 23 functions as a first gate insulating film, and the film thickness thereof is 100 nm. Further, in order to reduce the defect density at the interfaces, it is desirable for each of those stacked films to be formed continuously without being exposed to the air.

Subsequently, as shown in FIG. 13B, pulse light emitted from an Xe flash lamp is radiated over the whole surface of the substrate 21 from the above the first silicon oxide film (first gate insulating film) 23 to execute single pulse light annealing. The pulse irradiation time per pulse is 1 msec, and the total irradiation energy density is 1 J/cm². The pulse irradiation intensity with respect to the irradiation time may change in a form close to a rectangular shape or may be in a form close to a triangular wave.

Subsequently, as shown in FIG. 13C, the stacked film formed with the amorphous IGZO film 24 and the first silicon oxide film (first gate insulating film) 23 is patterned to a desired island shape. Further, as shown in FIG. 13D, a second silicon oxide film 33 functioning as a second gate insulating film is deposited to a thickness of 200 nm by sputtering.

Then, as shown in FIG. 13E, chromium of 100 nm is deposited as a gate electrode 22, and it is patterned to the shape of the gate electrode 22. At last, a third silicon oxide film (not shown) is deposited as a passivation film, thereby completing the thin film transistor.

In the eleventh exemplary embodiment, annealing using the pulse light is executed after forming the first silicon oxide film (first gate insulating film) 23. However, the annealing may be performed at any point as long as it is executed after forming the amorphous IGZO film 24.

For example, when pulse light annealing is performed after depositing the second silicon oxide film 33, effects such as increasing the quality of the second silicon oxide film (second gate insulating film) 33 can be expected due to the annealing effect. Furthermore, the pulse light annealing may also be performed at a plurality of steps, such as after depositing the first silicon oxide film (first gate insulating film) 23 and after depositing the second silicon oxide film (second gate insulating film).

While the eleventh exemplary embodiment is described by using an amorphous oxide semiconductor film as the semiconductor active layer, the present invention is not limited only to such case. It is possible to use a polycrystalline oxide semiconductor film such as a ZnO film or a crystalline oxide semiconductor.

When the oxide semiconductor containing indium, gallium, zinc, and tin is used as the oxide semiconductor film 24 that is the semiconductor active layer, it is possible to form the film at a room temperature. Thus, a resin substrate such as PET, a resin film, a glass substrate, or the like can be used as the substrate 21. Furthermore, a substrate such as a silicon substrate or a metal substrate can be used as well.

Other structures and effects thereof are the same as those of the tenth exemplary embodiment described above.

### Twelfth Exemplary Embodiment

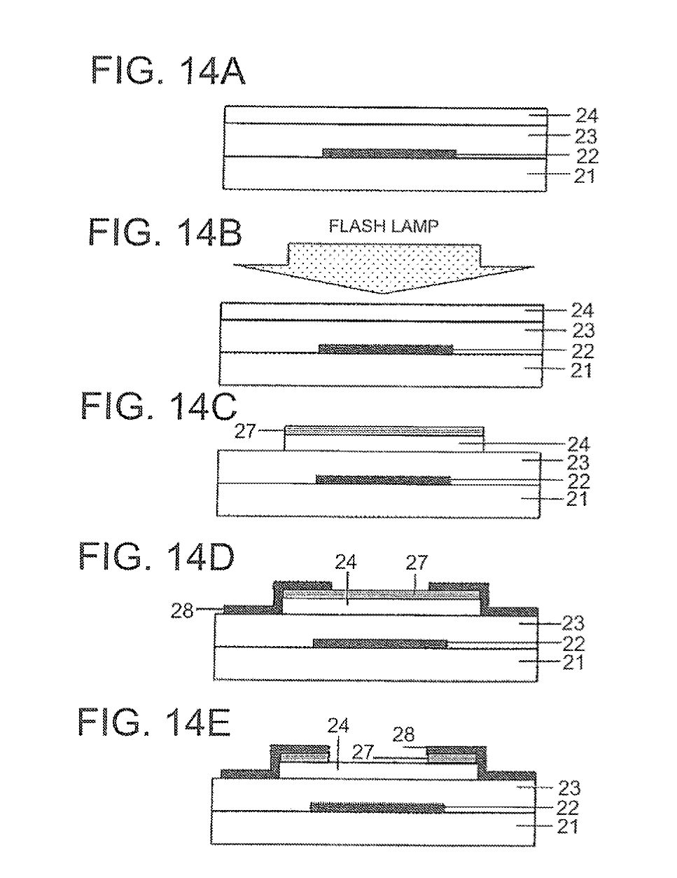

Next, a twelfth exemplary embodiment will be described by referring to FIG. 14.

FIG. 14 of the twelfth exemplary embodiment shows illustrations of a series of manufacturing steps which can manufacture another TFT that is equivalent to the TFTs (thin film transistors) obtained in the first exemplary embodiment described above.

Hereinafter, this will be described.

Note here that same reference numerals are applied to same structural members as those of the tenth exemplary embodiment described above.

First, as shown in FIG. 14A, chromium of 100 nm is deposited on a glass substrate 21 as a gate electrode 22, and it is then patterned to the shape of the gate electrode 22.

Subsequently, a first silicon oxide film (gate insulating film) 23 and an amorphous film (amorphous IGZO film) 24 made with an oxide of indium, gallium, and zinc are deposited in a stacked manner by sputtering. Note here that the first silicon oxide film functions as the gate insulating film, and the film thickness thereof is 300 nm. The amorphous IGZO film functions as the semiconductor active layer (oxide semiconductor film) 24, and the film thickness thereof is 20 nm. Further, in order to reduce the defect density at the interfaces, it is desirable for each of those stacked films to be formed continuously without being exposed to the air.

Subsequently, as shown in FIG. 14B, pulse light emitted from an Xe flash lamp is radiated over the whole surface of the substrate 21 from the above the amorphous film (amorphous IGZO film) 24 to execute single pulse light annealing. The pulse irradiation time per pulse is 1 msec, and the total irradiation energy density is 1 J/cm². The pulse irradiation intensity with respect to the irradiation time may change in a form close to a rectangular shape or may be in a form close to a triangular wave. In this exemplary embodiment, there is no other film provided on the amorphous IGZO film, so that it is not necessary to mind variations in the light intensities caused due to light interferences generated by other films. Therefore, stable light annealing process can be executed.

Thereafter, as shown in FIG. 14C, an ITO film 27 is deposited to be in contact with the source and drain, and the ITO film 27 and the amorphous IGZO film 24 are patterned to a desired island shape.

Furthermore, as shown in FIG. 14D, a metal film 28 is deposited as source/drain electrodes, and this metal film 28 is etched to be patterned to desired source/drain shapes. At this time, as show in FIG. 14E, the unnecessary ITO film 27 between the source and drain electrodes is also eliminated by etching. With this, the structure of the amorphous IGZO film 24 is improved by the pulse light annealing processing described above. Thereby, the chemical coupling between the adhesives can be made stronger, so that the resistance to the etching can be improved. As a result, it becomes possible to selectively etch and eliminate only the ITO film 27 while suppressing the etching amount of the amorphous IGZO film 24 to a small amount.

Subsequently, a second silicon oxide film (not shown) is deposited as a passivation film, and contact holes are opened at desired positions in the drain electrode part or the gate wiring and source wiring terminal part of the thin film transistor. At last, an ITO film 27 is deposited as a transparent electrode, and it is patterned to shapes of desired pixel electrode and terminal part electrode. Thereby, a thin film transistor array can be completed.

In the twelfth exemplary embodiment, annealing using the pulse light is executed immediately after forming the amorphous IGZO film 24. However, the annealing may be performed at any point as long as it is executed after forming the amorphous IGZO film 24.

For example, when pulse light annealing is performed after depositing the ITO film 27 as the last transparent electrode, effects such as obtaining high-quality passivation silicon oxide film and reduction in the resistance of the ITO film 27 as the transparent electrode can be expected due to the annealing effect. Furthermore, the pulse light annealing is not limited to be done with a single pulse. Radiations of a plurality of pulses such as ten pulse radiations at 10 Hz may be employed as well.

While the twelfth exemplary embodiment is described by referring to the case of the amorphous oxide semiconductor film, the present invention is not limited only to such case. It is possible to use a polycrystalline oxide semiconductor film such as a′ ZnO film or a crystalline oxide semiconductor. When the oxide semiconductor containing indium, gallium, zinc, and tin is used as the oxide semiconductor film (semiconductor active layer) 24, it is possible to form the film at a room temperature. Thus, a resin substrate such as PET, a resin film, a glass substrate, or the like can be used as the substrate. Furthermore, a substrate such as a silicon substrate or a metal substrate can be used as well.

Other structures and effects thereof are the same as those of the tenth exemplary embodiment described above.

In each of the exemplary embodiments described above, it is preferable to form a film of an insulator such as SiO₂ as a base film between the oxide semiconductor and the substrate. Through forming this base film, increase in the substrate temperature caused due to increase in the temperature of the oxide semiconductor can be suppressed. The film thickness of the base film is preferable to be 20 nm or more, since the thicker the base film is, the more the temperature increase in the substrate can be suppressed.

Further, the pulse light is used in each of the exemplary embodiments described above. It is possible to achieve substantial pulse light by using continuous light of a CW laser, for example. For example, a gas laser such as Ar laser or Kr laser may be used. In a case where the continuous light is used, the same effects as the case of the pulse laser can be achieved through controlling the time for radiating the continuous light to the substrate.

Specifically, the time for radiating the continuous light to the substrate can be controlled through moving the substrate while radiating the continuous light. This makes it possible to achieve the same effects as the case of radiating the pulse light while suppressing damages to the substrate.

Furthermore, plasma jet may be used instead of using the pulse light. In a case of using the plasma jet, the same effects as the case of radiating the pulse light can also be achieved through controlling the time for radiating the plasma jet to the substrate.

Specifically, the time for radiating the continuous light to the oxide semiconductor film can be controlled through moving the substrate while radiating the plasma jet. This makes it possible to achieve the same effects as the case of radiating the pulse light while suppressing damages to the substrate.

In other words, the main features of the present invention are three following points. 1. It is to reform the film by increasing the temperature of the oxide semiconductor through radiating the short pulse light such as the laser to the oxide semiconductor. 2. In a case where the oxide semiconductor is an amorphous oxide semiconductor such as IGZO, the irradiation condition is so set that the semiconductor can keep the amorphous characteristic even after radiating the short pulse light. 3. In a case where the oxide semiconductor is a polycrystalline oxide semiconductor such as ZnO, the irradiation condition is so set that the semiconductor can keep the polycrystalline characteristic even after radiating the short pulse light.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

### INDUSTRIAL APPLICABILITY

The present invention can make a contribution to cases where a fine oxide semiconductor film is formed on a glass substrate or a resin substrate such as PET. This makes it possible to manufacture the electronic components such as ICs of a fine property with good regenerability and yield.

What is claimed is:

1. A thin film device which uses an oxide semiconductor film deposited on a substrate as an active layer, wherein
the oxide semiconductor film is an amorphous oxide semiconductor to which pulse light is radiated.

2. The thin film device as claimed in claim 1, wherein
the oxide semiconductor film is formed by using, as a material, an oxide containing at least one element selected from zinc, gallium, indium, and tin.

3. The thin film device as claimed in claim 1, wherein
the oxide semiconductor film is formed by using an indium gallium zinc oxide film as a material.

4. The thin film device as claimed in claim 1, wherein
the oxide semiconductor film is formed by using a zinc oxide film as a material.

5. The thin film device as claimed in claim 1, comprising:
source/drain electrodes connected to the oxide semiconductor film; and
a gate electrode.

6. The thin film device as claimed in claim 1, comprising:
source/drain regions formed in a region of the oxide semiconductor film to which the pulse is radiated; and
a gate electrode.

7. A thin film device manufacturing method, comprising:
forming an oxide semiconductor film made with an amorphous oxide semiconductor on a substrate; and
radiating pulse light to the oxide semiconductor film to use the oxide semiconductor film made with the amorphous oxide semiconductor as an active layer.

8. The thin film device manufacturing method as claimed in claim 7, wherein
an oxide semiconductor film is formed by using an oxide semiconductor containing crystals, instead of forming the oxide semiconductor film made with the amorphous oxide semiconductor.

9. The thin film device manufacturing method as claimed in claim 7, wherein
the pulse light is of a lower energy than an energy with which a part of the oxide semiconductor film is crystallized, melted, or sublimated.

10. The thin film device manufacturing method as claimed in claim 7, which manufactures a thin film device comprising a gate electrode, a gate insulating film, an oxide semiconductor film, source/drain electrodes, and a passivation film, wherein
the pulse is radiated to the oxide semiconductor film in any of steps after depositing the oxide semiconductor film.

11. The thin film device manufacturing method as claimed in claim 7, wherein
a part of the oxide semiconductor film to which the pulse light is radiated is used as source/drain regions.

12. The thin film device manufacturing method as claimed in claim 7, wherein
pulse width of the pulse light is 1-1000 ns, and energy density per pulse of the pulse light is 1-1000 mJ/cm².

13. The thin film device manufacturing method as claimed in claim 7, wherein
pulse width of the pulse light is 0.001-100 ms, and energy density per pulse of the pulse light is 0.01-100 J/cm².

14. The thin film device manufacturing method as claimed in claim 7, wherein
the pulse light contains light with wavelength of 400 nm or less.

15. The thin film device manufacturing method as claimed in claim 7, wherein
the pulse light contains light with wavelength of 800 nm or more.

16. The thin film device manufacturing method as claimed in claim 7, wherein
the pulse light is an excimer laser.

17. The thin film device manufacturing method as claimed in claim 7, wherein
the pulse light is output light of a flash lamp.

18. The thin film device manufacturing method as claimed in claim 7, wherein
the pulse light is continuous light whose irradiation time is controlled.

19. The thin film device manufacturing method as claimed in claim 7, wherein
a plasma jet is used instead of the pulse light.

20. The thin film device manufacturing method as claimed in claim 7, wherein
process temperatures in steps other than a step of radiating the pulse light are set to 150 degrees C. or less.

21. The thin film device manufacturing method as claimed in claim 7, wherein:
a glass substrate or a resin substrate is used as the substrate, an indium gallium zinc oxide film is deposited on the substrate as an active layer, a flash lamp is used for radiation of the pulse light executed thereafter; and
as output light of the flash lamp, light with pulse width of 0.001-100 ms and energy density per pulse of 0.01-100 J/cm² is used.

22. The thin film device manufacturing method as claimed in claim 7, wherein:
a glass substrate or a resin substrate is used as the substrate, an indium gallium zinc oxide film is deposited on the substrate as an active layer, an excimer laser is used for radiation of the pulse light executed thereafter; and
as output light of the excimer laser, light with pulse width of 1-1000 ns and energy density per pulse of 1-1000 mJ/cm² is used.

23. The thin film device manufacturing method as claimed in claim 21, wherein
a zinc oxide film is deposited as the active layer, instead of the indium gallium zinc oxide film.
